(19) United States
(12) Patent Application Publication
(10) Pub. No.: US 2026/0123156 A1
(43) Pub. Date: Apr. 30, 2026

(54) DISPLAY DEVICE AND ELECTRONIC DEVICE INCLUDING THE SAME

(71) Applicant: Samsung Display Co., Ltd., Yongin-si (KR)

(72) Inventor: Mankyu Jo, Yongin-si (KR)

(21) Appl. No.: 19/331,959

(22) Filed: Sep. 17, 2025

(30) Foreign Application Priority Data
Oct. 28, 2024 (KR) 10-2024-0148971

(51) Int. Cl. H10H 29/853; H01L 25/075; H10H 29/49

(52) U.S. Cl. CPC H10H 29/853; H10H 29/49; H10W 90/00

(57) ABSTRACT

A display device having a display area and a non-display area includes a substrate and a plurality of light-emitting elements on the substrate and apart from one another along a first direction and a second direction crossing the first direction. The display area includes a plurality of first display areas extending in the first direction, overlapping the plurality of light-emitting elements arranged along the first direction, and apart from one another along the second direction, and a plurality of second display areas extending in the first direction, overlapping the plurality of light-emitting elements arranged along the first direction, and each arranged between two first display areas adjacent to each other among the plurality of first display areas. A portion of the substrate located in the first display area has a modulus different from a portion of the substrate located in the second display area.

### CROSS-REFERENCE TO RELATED APPLICATION

The present application claims priority to and the benefit of Korean Patent Application No. 10-2024-0148971, filed on October 28, 2024, in the Korean Intellectual Property Office, the entire disclosure of which is incorporated herein by reference.

### BACKGROUND

### Field

One or more embodiments of the present disclosure relate to a display device and an electronic device including the same.

### Description of the Related Art

With the development of display panels that visually display electronic signals, various display panels with enhanced characteristics (e.g., excellent or suitable characteristics), such as thinness, light weight, and/or low power consumption, and electronic devices including the same have been introduced and/or advanced. For example, research and development have been actively conducted on display panels that have suitable and/or versatile structures, such as flexible display panels, rollable display panels, and/or stretchable display panels, and on electronic devices including the same.

### SUMMARY

One or more aspects of embodiments of the present disclosure are directed toward a display device with improved stretchability and capable of displaying images with excellent or suitable quality even if (e.g., when) stretched and an electronic device including the same. However, these are merely examples, and the scope of the present disclosure is not limited thereto.

Additional aspects will be set forth in part in the description which follows and, in part, will be apparent from the description, or may be learned by practice of the presented embodiments of the disclosure.

According to one or more embodiments of the present disclosure, a display device having a display area and a non-display area includes a substrate and a plurality of light-emitting elements arranged on (e.g., on) the substrate and apart (e.g., spaced and/or apart) from one another along a first direction and a second direction crossing the first direction, wherein the display area includes a plurality of first display areas extending in the first direction, overlapping the plurality of light-emitting elements arranged along the first direction, and apart (e.g., spaced and/or apart) from one another along the second direction, and a plurality of second display areas extending in the first direction, overlapping the plurality of light-emitting elements arranged along the first direction, and each arranged between two first display areas adjacent to each other among the plurality of first display areas, wherein the substrate includes a plurality of first substrate portions respectively overlapping the plurality of first display areas and a plurality of second substrate portions respectively overlapping the plurality of second display areas, wherein a modulus of at least one of (e.g., at least one selected from among) the plurality of first substrate portions is greater than a modulus of at least one of (e.g., at least one selected from among) the plurality of second substrate portions.

In one or more embodiments, the display device may further include an encapsulation portion on (e.g., arranged on) the plurality of light-emitting elements, wherein the encapsulation portion may include a plurality of first encapsulation portions respectively overlapping the plurality of first display areas and a plurality of second encapsulation portions respectively overlapping the plurality of second display areas, wherein the plurality of first encapsulation portions (e.g., each of the plurality of first encapsulation portions) may include a plurality of first-first encapsulation portions respectively overlapping the plurality of light-emitting elements and a plurality of first-second encapsulation portions arranged between the plurality of first-first encapsulation portions.

In one or more embodiments, a modulus of at least one of (e.g., at least one selected from among) the plurality of first-second encapsulation portions may be greater than a modulus of at least one of (e.g., at least one selected from among) the plurality of second encapsulation portions.

In one or more embodiments, a modulus of at least one of (e.g., at least one selected from among) the plurality of first-first encapsulation portions may be equal to a modulus of at least one of (e.g., at least one selected from among) the plurality of first-second encapsulation portions.

In one or more embodiments, the plurality of light-emitting elements may include a plurality of first light-emitting elements arranged in a same column and each electrically connected to a first signal line and a plurality of second light-emitting elements arranged in a same column as the plurality of first light-emitting elements and each electrically connected to a second signal line.

In one or more embodiments, the display device may further include an auxiliary light-emitting element arranged between two light-emitting elements adjacent to each other among the plurality of light-emitting elements, wherein the auxiliary light-emitting element may be turned on if (e.g., when) the substrate is stretched in the first direction and may be turned off if (e.g., when) the substrate is compressed in the first direction.

In one or more embodiments, the auxiliary light-emitting element may be arranged in at least one of (e.g., at least one selected from among) the plurality of second display areas.

In one or more embodiments, the auxiliary light-emitting element may be provided in plurality, and the plurality of auxiliary light-emitting elements may be apart (e.g., spaced and/or apart) from one another along the second direction.

In one or more embodiments, the plurality of light-emitting elements may be arranged at equal intervals from each other along the first direction.

In one or more embodiments, the plurality of light-emitting elements may be arranged in a grid form.

According to one or more embodiments of the present disclosure, a display device having a display area and a non-display area includes a substrate, a plurality of light-emitting elements arranged on (e.g., on) the substrate and apart (e.g., spaced and/or apart) from one another along a first direction and a second direction crossing the first direction, and an encapsulation portion arranged on the plurality of light-emitting elements, wherein the display area includes a plurality of first display areas extending in the first direction, overlapping the plurality of light-emitting elements arranged along the first direction, and apart (e.g., spaced and/or apart) from one another along the second direction and a plurality of second display areas extending in the first direction, overlapping the plurality of light-emitting elements arranged along the first direction, and each arranged between two first display areas adjacent to each other among the plurality of first display areas, wherein the encapsulation portion includes a plurality of first encapsulation portions respectively overlapping the plurality of first display areas and a plurality of second encapsulation portions respectively overlapping the plurality of second display areas, wherein a modulus of at least one of (e.g., at least one selected from among) the plurality of first encapsulation portions is greater than a modulus of at least one of (e.g., at least one selected from among) the plurality of second encapsulation portions.

In one or more embodiments, the substrate may include a plurality of first substrate portions respectively overlapping the plurality of first display areas and a

plurality of second substrate portions respectively overlapping the plurality of second display areas, wherein the plurality of first substrate portions (e.g., each of the plurality of first substrate portions) may include a plurality of first-first substrate portions respectively overlapping the plurality of light-emitting elements and a plurality of first-second substrate portions arranged between the plurality of first-first substrate portions.

In one or more embodiments, a modulus of at least one of (e.g., at least one selected from among) the plurality of first-second substrate portions may be greater than a modulus of at least one of (e.g., at least one selected from among) the plurality of second substrate portions.

In one or more embodiments, a modulus of at least one of (e.g., at least one selected from among) the plurality of first-second substrate portions may be equal to a modulus of at least one of (e.g., at least one selected from among) the plurality of first-first substrate portions.

In one or more embodiments, the plurality of light-emitting elements may include a plurality of first light-emitting elements arranged in a same column and each electrically connected to a first signal line and a plurality of second light-emitting elements arranged in a same column as the plurality of first light-emitting elements and each electrically connected to a second signal line.

In one or more embodiments, the display device may further include an auxiliary light-emitting element arranged between two light-emitting elements adjacent to each other among the plurality of light-emitting elements, wherein the auxiliary light-emitting element may be turned on if (e.g., when) the substrate is stretched in the first direction and may be turned off if (e.g., when) the substrate is compressed in the first direction.

In one or more embodiments, the auxiliary light-emitting element may be arranged in at least one of (e.g., at least one selected from among) the plurality of second display areas.

In one or more embodiments, the auxiliary light-emitting element may be provided in plurality, and the plurality of auxiliary light-emitting elements may be apart (e.g., spaced and/or apart) from one another along the second direction.

In one or more embodiments, the plurality of light-emitting elements may be arranged at equal intervals from each other along the first direction.

In one or more embodiments, the plurality of light-emitting elements may be arranged in a grid form.

According to one or more embodiments of the present disclosure, an electronic device having a display area and a non-display area includes a stretchable display panel, wherein the stretchable display panel includes a substrate, a plurality of light-emitting elements arranged on (e.g., on) the substrate and apart (e.g., spaced and/or apart) from one another along a first direction and a second direction crossing the first direction, wherein the display area includes a plurality of first display areas extending in the first direction, overlapping the plurality of light-emitting elements arranged along the first direction, and apart (e.g., spaced and/or apart) from one another along the second direction and a plurality of second display areas extending in the first direction, overlapping the plurality of light-emitting elements arranged along the first direction, and each arranged between two first display areas adjacent to each other among the plurality of first display areas, wherein the substrate includes a plurality of first substrate portions respectively overlapping the plurality of first display areas and a plurality of second substrate portions respectively overlapping the plurality of second display areas, wherein a modulus of at least one of (e.g., at least one selected from among) the plurality of first substrate portions is greater than a modulus of at least one of (e.g., at least one selected from among) the plurality of second substrate portions.

Other aspects, features, and advantages of the disclosure will become better understood through the accompanying drawings, the appended claims, and the detailed description.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments of the disclosure will be more apparent from the following description taken in conjunction with the accompanying drawings, in which:

FIG. 1A is a perspective view schematically illustrating a display device according to one or more embodiments of the present disclosure;

FIG. 1B is a block diagram schematically illustrating a display device according to one or more embodiments of the present disclosure;

FIG. 2 is a perspective view schematically illustrating a display panel according to one or more embodiments of the present disclosure;

FIGS. 3A and 3B are each a perspective view illustrating the display panel of FIG. 2 stretched in a first direction according to one or more embodiments of the present disclosure;

FIG. 3C is a perspective view illustrating the display panel of FIG. 2 stretched in a second direction according to one or more embodiments of the present disclosure;

FIG. 3D is a perspective view illustrating the display panel of FIG. 2 stretched in the first direction and the second direction according to one or more embodiments of the present disclosure;

FIG. 3E is a perspective view illustrating the display panel of FIG. 2 stretched in a third direction according to one or more embodiments of the present disclosure;

FIG. 4 is a plan view schematically illustrating a display panel according to one or more embodiments of the present disclosure;

FIG. 5 is a plan view schematically illustrating a layout of pixels in a display panel, according to one or more embodiments of the present disclosure;

FIG. 6 is a cross-sectional view schematically illustrating a portion of a display panel according to one or more embodiments of the present disclosure;

FIGS. 7A ‒ 7C are each an equivalent circuit diagram of a pixel of a display panel, according to one or more embodiments of the present disclosure;

FIGS. 8A ‒ 8D are each a cross-sectional view schematically illustrating a light-emitting element of a display panel, according to one or more embodiments of the present disclosure;

FIG. 9A is a plan view schematically illustrating a display panel according to one or more embodiments of the present disclosure;

FIG. 9B is a plan view schematically illustrating a display panel according to one or more embodiments of the present disclosure;

FIGS. 10 and 11 are each a cross-sectional view schematically illustrating a portion of a display panel according to one or more embodiments of the present disclosure;

FIG. 12 is a plan view schematically illustrating a display panel according to one or more embodiments of the present disclosure;

FIGS. 13 and 14 are each a plan view schematically illustrating a display panel according to one or more embodiments of the present disclosure;

FIG. 15 is a plan view schematically illustrating a display panel according to one or more embodiments of the present disclosure;

FIG. 16 is a plan view schematically illustrating a display panel according to one or more embodiments of the present disclosure; and

FIGS. 17A ‒ 17G are perspective views schematically illustrating embodiments of electronic devices each including a display panel according to one or more embodiments of the present disclosure.

### DETAILED DESCRIPTION

Reference will now be made in more detail to one or more embodiments, examples of which are illustrated in the accompanying drawings, wherein like reference numerals refer to like elements throughout the disclosure, and duplicative descriptions thereof may not be provided for conciseness. In this regard, the presented embodiments may have different forms and should not be construed as being limited to the descriptions set forth herein. Accordingly, embodiments of the present disclosure are merely described in more detail, by referring to the drawings, to explain aspects of the present disclosure. As used herein, the term "and/or" or “or” may include any and all combinations of one or more of the associated listed items. Throughout the disclosure, the expressions such as “at least one of,” “one of,” and “selected from,” when preceding a list of elements, modify the entire list of elements and do not modify the individual elements of the list. For example, "at least one of a, b, or c", “at least one selected from among a, b, and c”, "at least one selected from among a to c", and/or the like, may indicate only a, only b, only c, both (e.g., simultaneously) a and b, both (e.g., simultaneously) a and c, both (e.g., simultaneously) b and c, all of a, b, and c, or variations thereof.

As the present description allows for one or more suitable changes and numerous embodiments, certain embodiments will be illustrated in the drawings and

described in more detail in the written description. Effects and features of the disclosure, and methods of achieving them will be clarified with reference to one or more embodiments described herein in more detail with reference to the drawings. However, the disclosure is not limited to the following embodiments and may be embodied in one or more suitable forms.

Hereinafter, example embodiments will be described in more detail with reference to the accompanying drawings. When describing embodiments with reference to the accompanying drawings, the same or corresponding elements are denoted by the same reference numerals, and redundant descriptions thereof may not be provided for conciseness.

In the following embodiments, the terms "first," "second," and/or the like are not used in a restrictive sense and are used to distinguish one element from another. Thus, a first element described could also be termed as a second or third element without departing from the spirit and scope of the disclosure.

The singular forms as used herein are intended to include the plural forms as well unless the context clearly indicates otherwise. For example, the singular forms “a,” “an,” “one,” and “the” are intended to include the plural forms as well, unless the context clearly indicates otherwise.

It will be further understood that the terms "include(s)/including" and/or "comprise(s)/comprising" and/or “have/has/having” used herein specify the presence of stated features or elements, but do not preclude the presence or addition of one or more other features or elements. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof. Further, the use of “may” when describing embodiments of the present disclosure refers to “one or more embodiments of the present disclosure.

It will be further understood that, if (e.g., when) a layer, region, or element is referred to as being "on" another layer, region, or element, it may be directly on the other layer, region, or element, but also one or more intervening layers, regions, or elements may be present therebetween. In contrast, if (e.g., when) an element is referred to as being “directly on” another element, there are no intervening element present therebetween.

Also, sizes of elements in the drawings may be exaggerated or reduced for convenience of explanation. For example, because sizes and thicknesses of elements in the drawings may be merely illustrated for convenience of explanation, embodiments of the disclosure are not necessarily limited thereto.

As used herein, an x-axis, a y-axis, and a z-axis are not limited to three axes of a cubic (e.g., three-dimension) coordinate system and may be interpreted in a broader sense. For example, the x-axis, the y-axis, and the z-axis may be normal (e.g., perpendicular) to one another or may represent different directions that are not normal (e.g., perpendicular) to one another.

When a certain embodiment is implemented differently, a specific process sequence may be performed differently from a sequence described herein. For example, two consecutively described processes may be performed substantially at the same time or performed in an order opposite to the stated order.

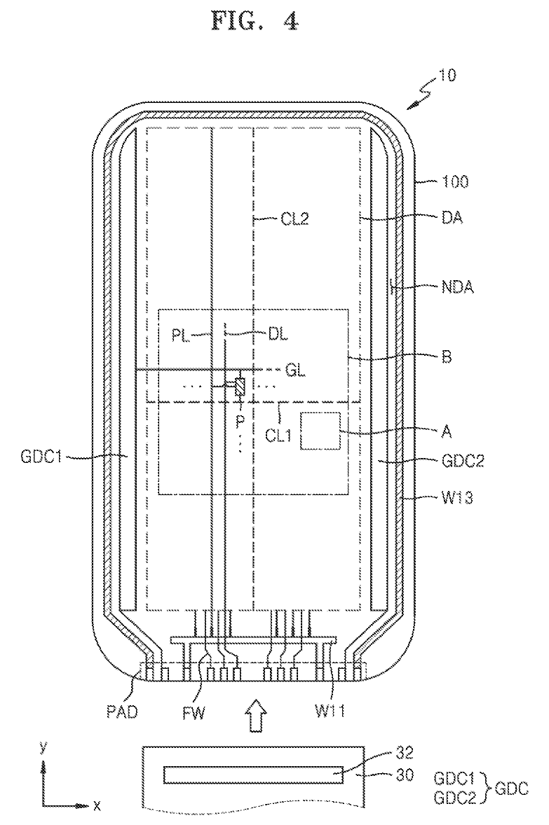

In the present disclosure, the expression "in a plan view" refers to a plane viewed from a direction normal (e.g., perpendicular) to a substrate (see 100 of FIG. 4). For example, the expression "A and B apart (e.g., spaced and/or apart) from each other in a plan view" refers to "A and B apart (e.g., spaced and/or apart) from each other if (e.g., when) viewed from a direction normal (e.g., perpendicular) to the substrate (see 100 of FIG. 4)."

In the present disclosure, the expression "in a cross-sectional view" refers to a plane cut in a direction normal (e.g., perpendicular) to the substrate (see 100 of FIG. 4). For example, the expression "A and B apart (e.g., spaced and/or apart) from each other in a cross-sectional view" refers to "A and B apart (e.g., spaced and/or apart) from each other in a plane cut in a direction normal (e.g., perpendicular) to the substrate (see 100 of FIG. 4)."

For example, "A and B apart from each other in a plan view" refers to that "A and B apart from each other when viewed from a direction perpendicular to the substrate," and "A and B apart from each other in a cross-sectional view" refers to that "A and B apart from each other in a plane cut in a direction perpendicular to the substrate" (see 100 of FIG. 4).

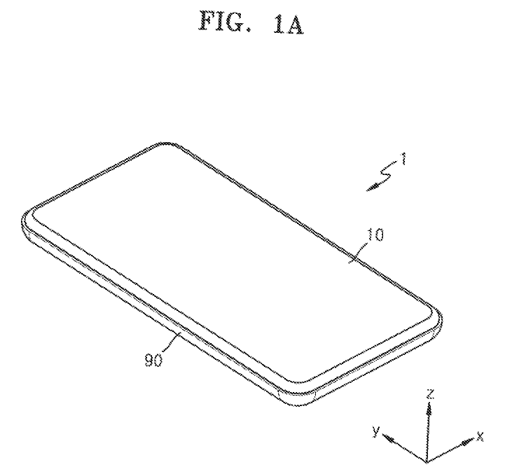

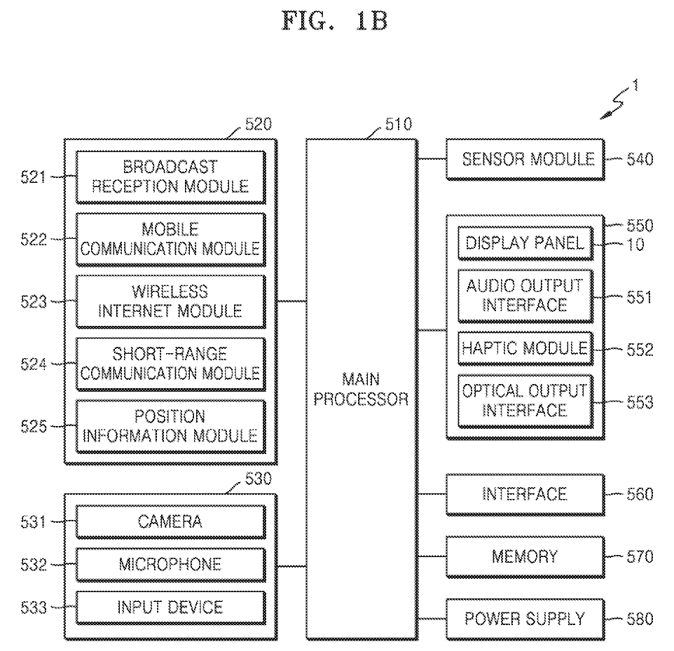

FIG. 1A is a perspective view schematically illustrating a display device 1 according to one or more embodiments of the present disclosure, and FIG. 1B is a block diagram schematically illustrating the display device 1 according to one or more embodiments of the present disclosure.

Referring to FIG. 1A and FIG. 1B, according to one or more embodiments, the display device 1 includes a display panel 10 and may be configured to display a moving image or a still image. In one or more embodiments, the display device 1 may be used as a display screen of a portable electronic device, such as a mobile phone, a smartphone, a tablet personal computer (PC), a mobile communication terminal, an electronic organizer, an e-book, a portable multimedia player (PMP), a navigation system, and/or an ultra mobile PC (UMPC). In one or more embodiments, the display device 1 may be used as a display screen of one or more suitable products, such as a television, a laptop, a monitor, a billboard, and/or an Internet of things (IoT) device. The display device 1 according to one or more embodiments may be used in a wearable device, such as a smart watch, a watch phone, a glass-type (kind) display, and/or a head mounted display (HMD). The display device 1 according to one or more embodiments may be used in a dashboard of an automobile, a center information display (CIDs) on the center fascia or a dashboard of an automobile, a room mirror display replacing side mirrors of an automobile, and displays on the rear sides of front seats to serve as entertainment devices for backseat passengers of an automobile.

FIG. 1A illustrates that the display device 1 according to one or more embodiments may be a smart phone. The display device 1 may include the display panel 10 and a lower cover 90 arranged below the display panel 10. The display device 1 may further include a cover window that covers an upper surface of the display panel 10.

The lower cover 90 may constitute an exterior of the display device 1 and may have an opening in the front surface thereof exposing a portion of the display panel 10. The lower cover 90 may have a shape in which a surface corresponding to the display panel 10 is opened and may be assembled with the display panel 10. In one or more embodiments, the lower cover 90 may constitute a lower exterior of the display device 1. A display circuit board, components, a main circuit board, a battery, a driver, and/or the like may be arranged between the display panel 10 and the lower cover 90. The lower cover 90 may include plastic, metal, or both (e.g., simultaneously) plastic and metal.

The display device 1 may include a main processor 510, a wireless communication module 520, an input interface 530, a sensor module 540, an output interface 550, an interface 560, a memory 570, and/or a power supply 580.

The main processor 510 may be configured to control all functions of the display device 1. For example, the main processor 510 may be configured to output digital video data to a data driver through a display circuit board, so that the display panel 10 displays an image. The main processor 510 may be configured to receive sensing data from a touch sensor driver. The main processor 510 may be configured to determine the presence or absence of a user touch based on the sensing data and may be configured to execute an operation corresponding to a user's direct touch or proximity touch. The main processor 510 may be an application processor, a central processing unit, or a system chip, which is implemented as an integrated circuit.

A camera 531 may process image frames (e.g., still images or moving images) obtained by an image sensor in a camera mode and may output the processed image frames to the main processor 510. The camera 531 may include at least one of a camera sensor (e.g., charge-coupled device (CCD), complementary metal-oxide semiconductor (CMOS), and/or the like), a photo sensor (or an image sensor), or a laser sensor. The camera 531 may be connected to the image sensor and may be configured to process an image input to the image sensor.

The wireless communication module 520 may include at least one of a broadcast reception module 521, a mobile communication module 522, a wireless Internet module 523, a short-range communication module 524, or a position information module 525.

The broadcast reception module 521 may be configured to receive broadcast signals and/or broadcast-related information from an external broadcast management server over a broadcast channel. The broadcast channel may include a satellite channel and a terrestrial channel.

The mobile communication module 522 may be configured to transmit and receive radio signals to and from at least one of a base station, an external terminal, or a server on a mobile communication network set up in accordance with technical standards or communication schemes for mobile communication (e.g., Global System for Mobile communication (GSM), Code Division Multiple Access (CDMA), Code Division Multiple Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTE-A), and/or the like). The radio signals may include voice call signals, video call signals, or one or more suitable types (kinds) of data according to text/multimedia message transmission and reception.

The wireless Internet module 523 may refer to a module for wireless Internet access. The wireless Internet module 523 may be configured to transmit and receive radio signals in a communication network in accordance with wireless Internet technologies. Non-limiting examples of the wireless Internet technologies may include Wireless Local Area Network (LAN) (WLAN), Wireless-Fidelity (Wi-Fi), Wi-Fi Direct, and Digital Living Network Alliance (DLNA).

The short-range communication module 524 may be provided for short-range communication and may support short-range communication by using at least one of Bluetooth™, Radio Frequency Identification (RFID), Infrared Data Association (IrDA), Ultra Wideband (UWB), ZigBee, Near Field Communication (NFC), Wi-Fi, Wi-Fi Direct, or Wireless Universal Serial Bus (USB). The short-range communication module 524 may be configured to support wireless communication between the display device 1 and a wireless communication system, between the display device 1 and another electronic device, or between the display device 1 and a network where another electronic device (or an external server) is located, through a short-range wireless communication network (a wireless area network). The short-range wireless communication network may be a wireless personal area network. The other electronic device may be a wearable device capable of exchanging (or linking) data with the display device 1.

The position information module 525 may be a module configured to obtain a position (or current position) of the display device 1 and may include a Global Positioning System (GPS) module and/or a Wi-Fi module.

The input interface 530 may include an image input interface such as the camera 531 configured to input an image signal, an audio input interface such as a microphone 532 configured to input an audio signal, and an input device 533 configured to receive information from a user.

The camera 531 may be configured to process image frames (e.g., still images or moving images) obtained by an image sensor in a video call mode or an image-capturing mode. The processed image frames may be displayed on the display panel 10 or stored in the memory 570.

The microphone 532 may be configured to process an external audio signal into electrical voice data. The processed electrical voice data may be variously utilized depending on the functions performed by the display device 1 (or the application executed by the display device 1).

The main processor 510 may be configured to control the operation of the display device 1 to correspond to information input through the input device 533. The input device 533 may include a touch input interface or a mechanical input interface, such as a button, a dome switch, a jog wheel, or a jog switch, which is located on a rear or side surface of the display device 1. The touch input interface may include a touch screen layer of the display panel 10.

The sensor module 540 may include one or more sensors configured to sense at least one of internal information of the display device 1, information about an ambient environment around (e.g., surrounding) the display device 1, or user information and generate a sensing signal corresponding thereto. The main processor 510 may be configured to, based on the sensing signal, control the driving or operation of the display device 1 or perform data processing, functions, or operations related to applications installed on the display device 1. The sensor module 540 may include at least one of a proximity sensor, an illumination sensor, an acceleration sensor, a magnetic sensor, a G-sensor, a gyroscope sensor, a motion sensor, an RGB sensor, an infrared (IR) sensor, a finger scan sensor, an ultrasonic sensor, an optical sensor, a battery gauge, an environmental sensor (e.g., a barometer, a hygrometer, a thermometer, a radiation detection sensor, a heat detection sensor, a gas detection sensor, and/or the like), or a chemical sensor (e.g., an electronic nose, a healthcare sensor, a biometric recognition sensor, and/or the like).

The output interface 550 may be configured to generate output related to the sense of vision, hearing, or touch and may include at least one of the display panel 10, an audio output interface 551, a haptic module 552, or an optical output interface 553.

The display panel 10 may be configured to display (output) information processed by the display device 1. For example, the display panel 10 may be configured to display execution screen information of an application driven by the display device 1, or user interface (UI) or graphical user interface (GUI) information based on the execution screen information. The display panel 10 may include a display layer configured to display an image and a touch screen layer configured to sense user touch input. Due to this, the display panel 10 may function as one of the input devices 533 configured to provide an input interface between the display device 1 and a user and may also function as one of the output interface 550 configured to provide an output interface between the display device 1 and the user.

The audio output interface 551 may be configured to output audio data received from the wireless communication module 520 or audio data stored in the memory 570 in a signal reception mode, a call mode, a recording mode, a voice recognition mode, a broadcast reception mode, and/or the like. The audio output interface 551 may be configured to output an audio signal related to the function performed by the display device 1 (e.g., a call signal reception sound, a message reception sound, and/or the like). The audio output interface 551 may include a receiver and a speaker. At least one of the receiver or the speaker may be a sound generator that is attached to a lower portion of the display panel 10 and configured to vibrate the display panel 10 to output sound. The sound generator may be a piezoelectric element or a piezoelectric actuator that contracts and expands in response to an electrical signal, or may be an exciter configured to generate a magnetic force by using a voice coil and vibrates the display panel 10.

The haptic module 552 may be configured to generate one or more suitable tactile effects that a user may feel. The haptic module 552 may be configured to provide vibration to the user as a tactile effect. The haptic module 552 may be configured to transmit the tactile effect through direct contact and allow the user to feel the tactile effect through the muscle sense of fingers or arms of the user, and/or the like.

The optical output interface 553 may be configured to output a signal for notifying an occurrence of an event by using light from a light source. Non-limiting examples of the event occurring in the display device 1 may include message reception, call signal reception, missed call, alarm, schedule reminder, email reception, notification of information through an application, and/or the like. The signal output by the optical output interface 553 may be implemented as the display device 1 emits light of one or more colors to the front or back of the display device 1. The output of the signal may be terminated if (e.g., when) the display device 1 senses a user's identification of the event.

The interface 560 may serve as a path for one or more suitable types (kinds) of external devices connected to the display device 1. The interface 560 may include at least one of a wired/wireless headset port, an external charger port, a wired/wireless data port, a memory card port, a port for connection to a device including an identification module, an audio input/output (I/O) port, a video I/O port, or an earphone port. The display device 1 may be configured to perform appropriate or suitable control related to the connected external device in response to the connection of an external device to the interface 560.

The memory 570 may be configured to store data that supports one or more suitable functions of the display device 1. The memory 570 may be configured to store

a plurality of applications (application programs) driven by the display device 1, data for the operation of the display device 1, and instructions. At least some applications may be downloaded from an external server through wireless communication. The memory 570 may be configured to store applications for the operation of the main processor 5100 and may also be configured to temporarily store I/O data, for example, a phone book, messages, still images, and/or moving images. In one or more embodiments, the memory 570 may be configured to store haptic data for one or more suitable patterns of vibration provided to the haptic module 552 and audio data related to one or more suitable sounds provided to the audio output interface 551. The memory 570 may include at least one type (kind) of storage medium selected from among a flash memory-type (kind) memory, a hard disk-type (kind) memory, a silicon disk drive (SDD)-type (kind) memory, a multimedia card micro-type (kind) memory, a card-type (kind) memory (e.g., secure digital (SD) or extreme digital (XD) memory), a random access memory (RAM), a static random access memory (SRAM), a read-only memory (ROM), an electrically erasable programmable read-only memory (EEPROM), a programmable read-only memory (PROM), a magnetic memory, a magnetic disc, and an optical disc.

The power supply 580 may be configured to receive external power and/or internal power under the control by the main processor 5100 and supply the external power and/or the internal power to each component included in the display device 1. In one or more embodiments, the power supply 580 may include a battery. In addition, the power supply 580 may include a connection port. The connection port may be configured as an example of the interface 560 to which an external charger that supplies power for charging the battery is electrically connected. In one or more embodiments, the power supply 580 may be configured to charge the battery in a wireless manner without using a connection port.

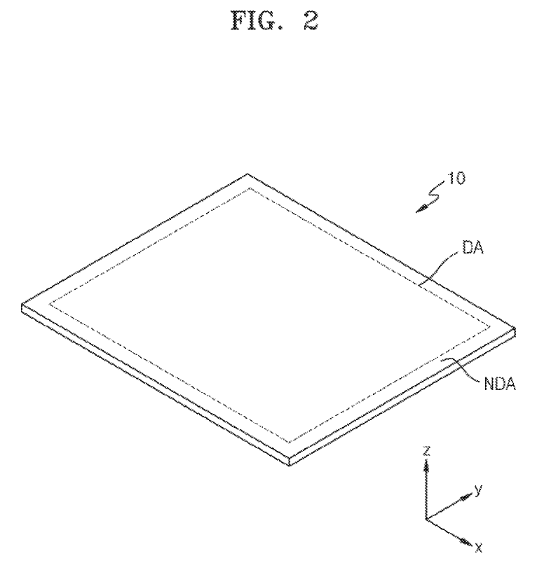

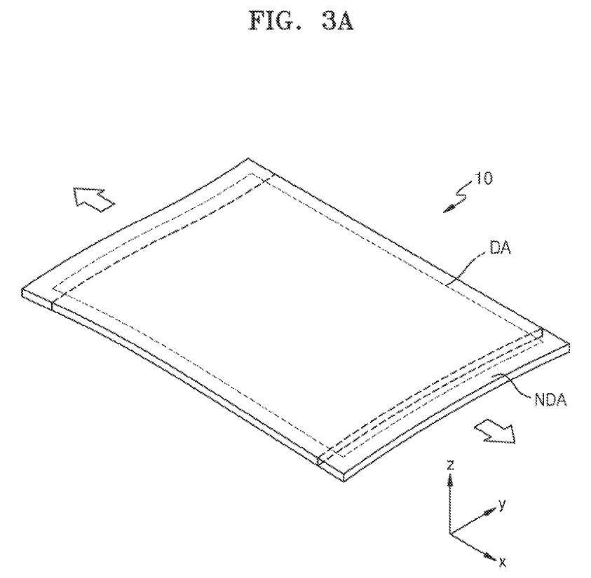

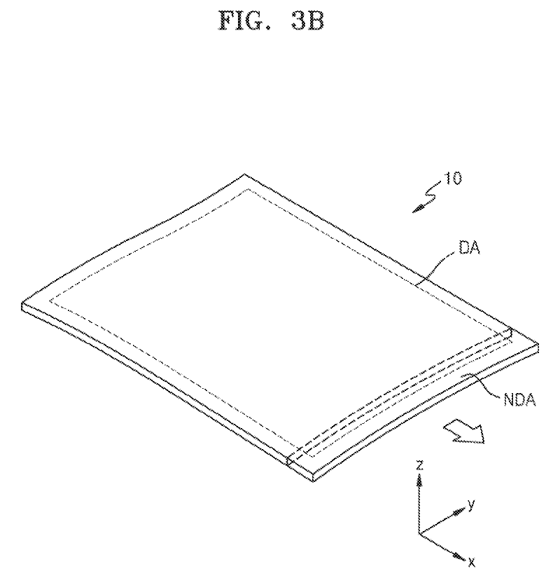

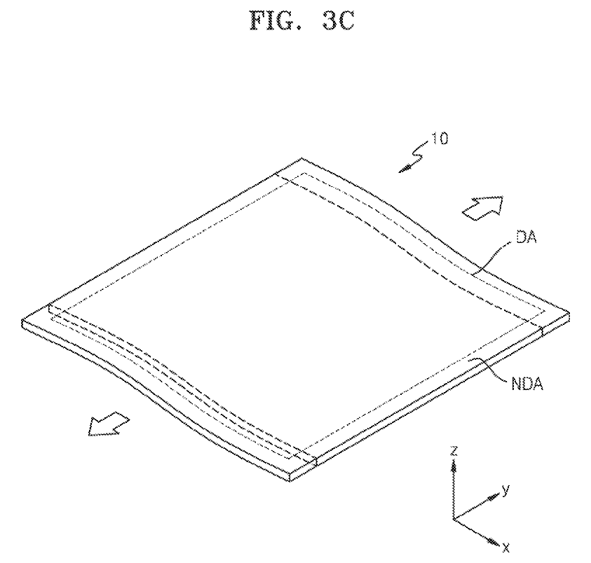

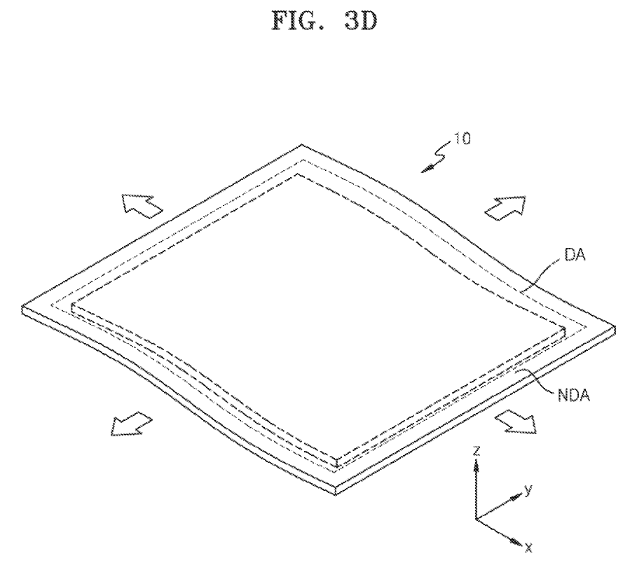

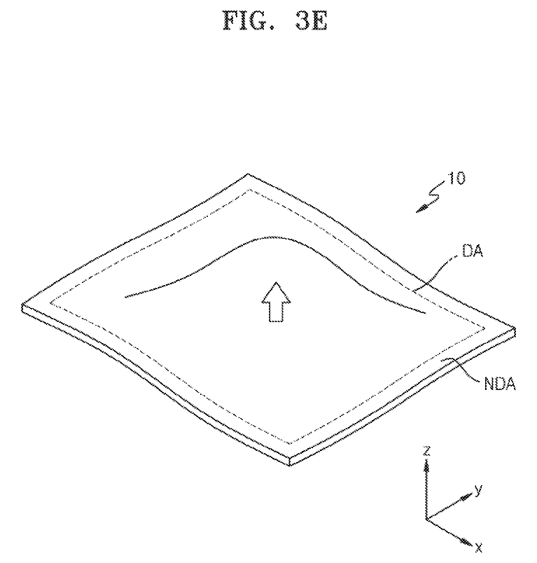

FIG. 2 is a perspective view schematically illustrating a display panel 10 according to one or more embodiments of the present disclosure. FIGS. 3A and 3B are perspective views illustrating the display panel 10 of FIG. 2, which is stretched in a first direction. FIG. 3C is a perspective view illustrating the display panel 10 of FIG. 2, which is stretched in a second direction. FIG. 3D is a perspective view illustrating the display panel 10 of FIG. 2, which is stretched in the first direction and the second direction. FIG. 3E is a perspective view illustrating the display panel 10 of FIG. 2, which is stretched in a third direction.

Referring to FIG. 2, the display panel 10 may include a display area DA and a non-display area NDA. The display area DA may include a plurality of pixels. The display panel 10 may be configured to provide a certain image by using light emitted from the pixels. The non-display area NDA may be arranged outside the display area DA. In one or more embodiments, the non-display area NDA may completely be around (e.g., surround) the display area DA.

The display panel 10 may be stretched or compressed in one or more suitable directions. For example, the display panel 10 may be stretched in the first direction (e.g., the +x direction and/or the -x direction) by an external force applied by an external object or a user. In one or more embodiments, as illustrated in FIGS. 3A and 3B, the display area DA and/or the non-display area NDA of the display panel 10 may be stretched in the first direction (e.g., the +x direction and/or the -x direction). For example, as illustrated in FIG. 3A, the display panel 10 may be stretched along both the +x direction and the -x direction, or as illustrated in FIG. 3B, the display panel 10 may be stretched only along the +x direction while one side of the display panel 10 is fixed.

The display panel 10 may be stretched in the second direction (e.g., the +y direction and/or the -y direction) by an external force applied by an external object or a user. In one or more embodiments, as illustrated in FIG. 3C, the display area DA and/or the non-display area NDA of the display panel 10 may be stretched in both the +y direction and the -y direction. In one or more embodiments, the display panel 10 may be stretched in the +y direction or the -y direction while one side of the display panel 10 is fixed.

The display panel 10 may be stretched in a plurality of directions, for example, the first direction (e.g., the +x direction and/or the -x direction) and the second direction (e.g., the +y direction and/or the -y direction) by an external force applied by an external object or a part of a user’s body. As illustrated in FIG. 3D, in one or more embodiments, the display area DA and/or the non-display area NDA of the display panel 10 may be stretched in the ±x direction and the ±y direction.

The display panel 10 may also be stretched in the third direction (e.g., the +z direction or the -z direction) by an external force applied by an external object or a part of a user’s body. In one or more embodiments, FIG. 3E illustrates that a portion of the display panel 10, for example, a portion of the display area DA, protrudes in the +z direction. In one or more embodiments, a portion of the display panel 10, for example, a portion of the display area DA, may protrude along the +z direction (or may be recessed along the -z direction).

Although FIGS. 3A to 3E illustrate that the display device 1 is stretched in the first direction, the second direction, and/or the third direction, embodiments of the present disclosure are not limited thereto. In one or more embodiments, the display panel 10 may be deformed into one or more suitable irregular shapes. For example, the display panel 10 may be bent or twisted with respect to two or more axes.

FIG. 4 is a plan view schematically illustrating a display panel 10 according to one or more embodiments of the present disclosure.

Referring to FIG. 4, the display panel 10 may include a display area DA and a non-display area NDA around (e.g., surrounding) the display area DA. Pixels P may be arranged in the display area DA of a substrate 100. The pixels P may be configured to display an image by using light emitted from light-emitting elements. The light-emitting elements may each be configured to emit (e.g., externally emit), for example, red light, green light, or blue light.

In one or more embodiments, the display area DA may be symmetrical with respect to a first center lineCL1 extending in a first direction (e.g., x direction) and a second center line CL2 extending in a second direction (e.g., y direction). For example, the intersection of the first center line CL1 and the second center line CL2 may be located at the center of the display area DA. Although FIG. 4 illustrates that a planar shape of the display area DA is rectangular, this is merely an example and the shape of the display area DA is not limited thereto.

The light-emitting elements may be electrically connected to pixel circuits, respectively. The pixel circuits may each include transistors and a storage capacitor. The pixel circuits may be electrically connected to peripheral circuits and peripheral lines arranged in the non-display area NDA, respectively. The peripheral circuits arranged in the non-display area NDA may include a gate driving circuit GDC and a terminal portion PAD. The peripheral lines may include a driving voltage supply line W11, a common voltage supply line W13, and a fan-out line FW.

The gate driving circuit GDC may include drivers configured to provide electrical signals to gate electrodes of the transistors electrically connected to the light-emitting elements. For example, the gate driving circuit GDC may be configured to apply scan signals to the pixel circuits respectively corresponding to the pixels P through gate lines GL.

The gate driving circuit GDC may include a first gate driving circuit GDC1 and a second gate driving circuit GDC2 respectively arranged on two sides (e.g., two opposite sides) of the display panel 10 with the display area DA therebetween. The second gate driving circuit GDC2 may be arranged on the opposite side of the first gate driving circuit GDC1 with respect to the display area DA and may be approximately parallel to the first gate driving circuit GDC1. Some pixel circuits may be electrically connected to the first gate driving circuit GDC1, and the remaining pixel circuits may be electrically connected to the second gate driving circuit GDC2. In certain embodiments, the second gate driving circuit GDC2 may not be provided. In these certain embodiments, the pixel circuits may all be electrically connected to the first gate driving circuit GDC1.

The terminal portion PAD may be arranged on a (e.g., one) side of the substrate 100. The terminal portion PAD may be exposed without being covered by an insulating layer and may be connected to a display circuit board 30. A display driver 32 may be arranged on the display circuit board 30. The display driver 32 may be configured to generate a control signal to be transmitted to the first gate driving circuit GDC1 and the second gate driving circuit GDC2. The display driver 32 may be configured to generate a data signal. The generated data signal may be transmitted to the pixel circuits of the pixels P through the fan-out line FW and a data line DL connected to the fan-out line FW.

The display driver 32 may be configured to supply a first power supply voltage (see VDD of FIG. 7A) to the driving voltage supply line W11 and supply a second power supply voltage (see VSS of FIG. 7A) to the common voltage supply line W13. The first power supply voltage (see VDD of FIG. 7A) may be applied to the pixel circuit of the pixel P through a driving voltage line PL connected to the driving voltage supply line W11, and the second power supply voltage (see VSS of FIG. 7A) may be connected to the common voltage supply line W13 and may be applied to an opposite electrode of the light-emitting element. The driving voltage supply line W11 may extend from a lower side of the display area DA along the x direction. The common voltage supply line W13 may have a loop shape with one side open and may partially be around (e.g., surround) the display area DA.

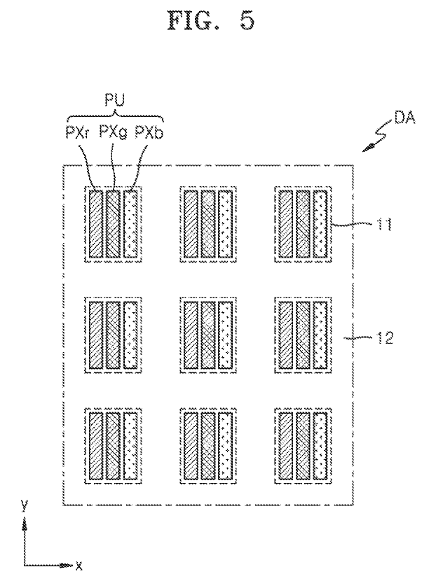

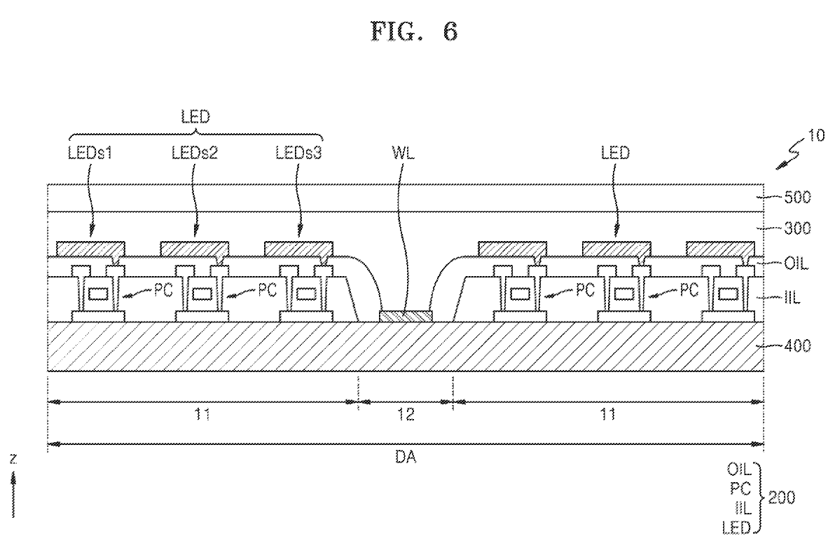

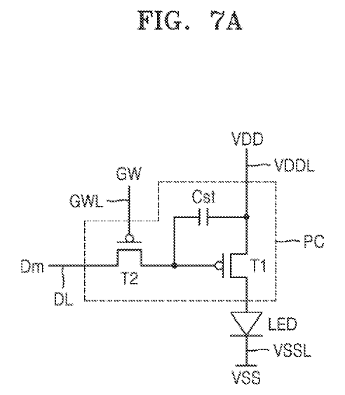

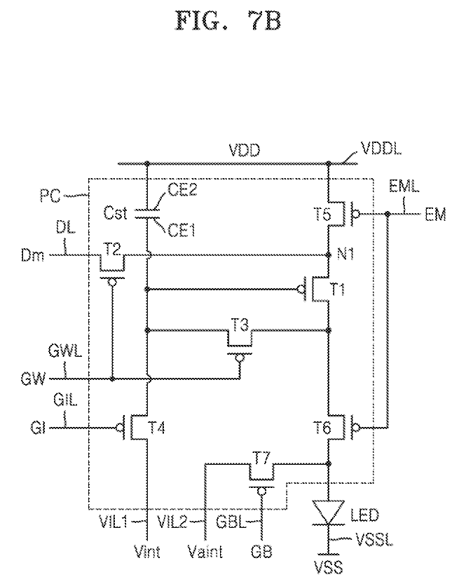

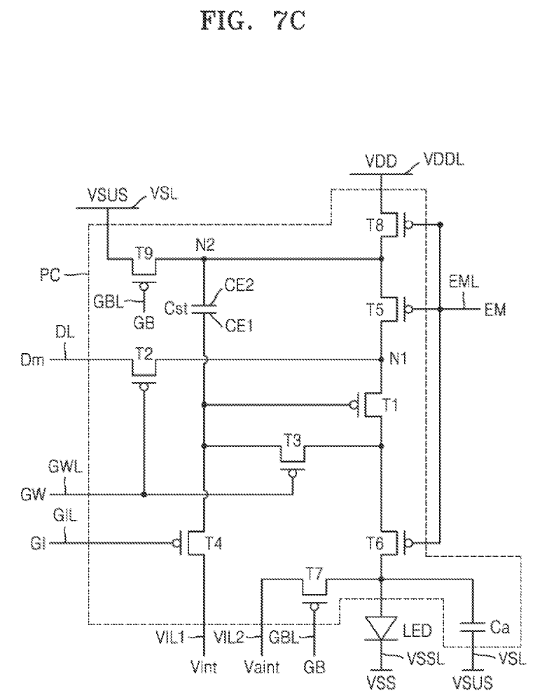

FIG. 5 is a plan view schematically illustrating a layout of pixels in the display panel 10, according to one or more embodiments of the present disclosure. For example, FIG. 5 is an enlarged view of region A of FIG. 4.

Referring to FIG. 5, a plurality of pixels PXr, PXg, and PXb may be arranged in the display area DA of the display panel 10. The display area DA may include a pixel area 11 and a connection area 12 outside the pixel area 11. A red pixel PXr, a green pixel PXg, and a blue pixel PXb may be arranged in the pixel area 11. The red pixel PXr, the green pixel PXg, and the blue pixel PXb may constitute one pixel unit PU. Pixel units PU may be repeatedly arranged in the display area DA.

Signal lines electrically connected to adjacent pixels may be arranged in the connection area 12. If (e.g., when) the display panel 10 is stretched, the connection area 12 may be stretched relatively more than the pixel area 11. In one or more embodiments, connection lines arranged in the connection area 12 may include a material having both (e.g., simultaneously) excellent or suitable stretchability and excellent or suitable electrical properties. For example, in one or more embodiments, the connection lines arranged in the connection area 12 may include a liquid metal, and/or the like. The pixel areas 11 may be arranged at certain intervals from one another along the first direction (e.g., the x direction) and the second direction (e.g., the y direction).

FIG. 6 is a cross-sectional view schematically illustrating a portion of a display panel 10 according to one or more embodiments of the present disclosure.

Referring to FIG. 6, a display area DA may include a pixel area 11 and a connection area 12. The connection area 12 may be an area that connects adjacent pixel areas 11 to each other. The pixel area 11 may include a light-emitting element LED and a circuit (e.g., a pixel circuit PC) configured to drive the light-emitting element LED. The connection area 12 may include a connection line WL included in a signal line configured to supply a signal to each of the pixel circuits PC.

The pixel area 11 and the connection area 12 may be formed on a substrate 400. For example, the substrate 400 may define the pixel area 11 and the connection area 12. The light-emitting element LED and the pixel circuit PC may be arranged in the pixel area 11 of the substrate 400, and the connection line WL may be arranged in the connection area 12 of the substrate 400.

The substrate 400 may be to absorb stress occurring if (e.g., when) the display panel 10 is stretched. The substrate 400 may include an elastomer. For example, in one or more embodiments, the substrate 400 may include at least one of a thermoplastic polyurethane, a silicone, a thermoplastic rubber, an elastolefin, a thermoplastic olefin, a polyamide, a polyether block amide, synthetic polyisoprene, polybutadiene, a chloroprene rubber, a butyl rubber, poly(styrene-butadiene), an epichlorohydrin rubber, a polyacrylic rubber, a silicone rubber, a fluorosilicone rubber, a fluoroelastomer, ethylene-vinyl acetate, polydimethylsiloxane (PDMS), or ecoflex.

A display layer 200 may be arranged in the pixel area 11 of the substrate 400. The display layer 200 may include an inorganic insulating layer IIL, the pixel circuit PC, an organic insulating layer OIL, and the light-emitting element LED. The pixel circuit PC may be arranged on the substrate 400, and the inorganic insulating layer IIL may be arranged between electrodes included in the pixel circuit PC. The organic insulating layer OIL may be arranged on the inorganic insulating layer IIL to cover the pixel circuit PC.

The light-emitting element LED may be arranged on the substrate 400. The light-emitting element LED may be arranged on the organic insulating layer OIL and may be electrically connected to the corresponding pixel circuit PC. In one or more embodiments, the light-emitting element LED may include a first sub-light-emitting element LEDs1, a second sub-light-emitting element LEDs2, and a third sub-light-emitting element LEDs3. The inorganic insulating layer IIL may include an inorganic insulating material, such as silicon nitride and/or silicon oxide, and the organic insulating layer OIL may include an organic insulating material, such as a polyimide.

In one or more embodiments, one pixel unit (see PU of FIG. 5) may be arranged in one pixel area 11. As described above, the pixel unit (see PU of FIG. 5) may include a red pixel (see PXr of FIG. 5), a green pixel (see PXg of FIG. 5), and a blue pixel (see PXb of FIG. 5). The red pixel (see PXr of FIG. 5A) may include the first sub-light-emitting element LEDs1, the green pixel (see PXg of FIG. 5A) may include the second sub-light-emitting element LEDs2, and the blue pixel (see PXb of FIG. 5A) may include the third sub-light-emitting element LEDs3. For example, the first sub-light-emitting element LEDs1 may be configured to emit (e.g., externally emit) red light, the second sub-light-emitting element LEDs2 may be configured to emit (e.g., externally emit) green light, and the third sub-light-emitting element LEDs3 may be configured to emit (e.g., externally emit) blue light. In one or more embodiments, the light-emitting element LED may be configured to externally emit white light (e.g., combined white light).

The connection line WL may be arranged in the connection area 12 of the substrate 400. In one or more embodiments, as illustrated in FIG. 6, the connection line WL may be arranged on the substrate 400. In one or more embodiments, the connection line WL may be arranged in the substrate 400. The connection line WL may include a material having both (e.g., simultaneously) enhanced (e.g., excellent or suitable) stretchability and enhanced (e.g., excellent or suitable) electrical properties. In one or more embodiments, the connection lines WL arranged in the connection area 12 may each include a liquid metal. In one or more embodiments, the connection lines WL may each include a metal nanostructure and an elastic polymer. In one or more embodiments, the connection lines WL may each include a conductive composite material including an elastomer.

The organic insulating layer OIL may be arranged in the connection area 12 of the substrate 400. In one or more embodiments, the organic insulating layer OIL arranged in the connection area 12 may be a portion of the organic insulating layer OIL arranged in the pixel area 11 and extending up to the connection area 12. When the display panel 10 is stretched, the connection area 12 may be deformed relatively more than the pixel area 11. Accordingly, unlike the pixel area 11, a layer that includes an inorganic insulating material prone to cracking may not be present in the connection area 12.

In one or more embodiments, a charging portion 300 may be arranged on the light-emitting element LED. The charging portion 300 may be arranged in both (e.g., simultaneously) the pixel area 11 and the connection area 12. For example, the charging portion 300 may be arranged to cover the entire display area DA. The charging portion 300 may cover the light-emitting element LED and the connection line WL. The charging portion 300 may be to absorb stress occurring if (e.g., when) the display panel 10 is stretched. For example, the charging portion 300 may prevent or reduce stress, which may occur if (e.g., when) the display panel 10 is stretched, from being transmitted to the light-emitting element LED and the pixel circuit PC.

The charging portion 300 may include an elastomer. For example, in one or more embodiments, the charging portion 300 may include at least one of a thermoplastic polyurethane, a silicone, a thermoplastic rubber, an elastolefin, a thermoplastic olefin, a polyamide, a polyether block amide, synthetic polyisoprene, polybutadiene, a chloroprene rubber, a butyl rubber, poly(styrene-butadiene), an epichlorohydrin rubber, a polyacrylic rubber, a silicone rubber, a fluorosilicone rubber, a fluoroelastomer, ethylene-vinyl acetate, or PDMS. In one or more embodiments, the charging portion 300 may include a material that is substantially identical to a material of the substrate 400. However, embodiments of the present disclosure are not limited thereto, for example, in one or more embodiments, the charging portion 300 may include a material that is different from a material of the substrate 400.

An encapsulation portion 500 may be arranged on the charging portion 300. The encapsulation portion 500 may be arranged on a plurality of light-emitting elements LED, and the charging portion 300 may be arranged between the plurality of light-emitting elements LED and the encapsulation portion 500. For example, the charging portion 300 may be configured to charge a space between the plurality of light-emitting elements LED and the encapsulation portion 500. The encapsulation portion 500 may block ambient moisture, air, and/or the like.

The encapsulation portion 500 may include a flexible material that is stretchable. For example, in one or more embodiments, the encapsulation portion 500 may include a polymer resin, such as polyethersulfone, polyarylate, polyether imide, polyethylene naphthalate, polyethylene terephthalate, polyphenylene sulfide, polyimide, polycarbonate, cellulose triacetate, cellulose acetate, or cellulose propionate. In one or more embodiments, the encapsulation portion 500 may be a single layer including the polymer resin described above. In one or more embodiments, the encapsulation portion 500 may have a multilayer structure including a base layer and a barrier layer. The base layer may include the polymer resin described above and the barrier layer may include an inorganic insulating material. The encapsulation portion 500 including the polymer resin may be flexible, rollable, and/or bendable.

FIGS. 7A to 7C are each an equivalent circuit diagram of a pixel (see P of FIG. 4) of a display panel (see 10 of FIG. 4), according to one or more embodiments of the present disclosure.

Referring to FIG. 7A, in one or more embodiments, a light-emitting element LED corresponding to the pixel may be electrically connected to a pixel circuit PC. The pixel circuit PC may include a first transistor T1, a second transistor T2, and a storage capacitor Cst. The pixel circuit PC may be electrically connected to signal lines and voltage lines. The signal lines may include a data line DL and a gate line (see GL of FIG. 4), such as a scan signal line GWL. The voltage lines may include a first voltage line VDDL. In this regard, the first voltage line VDDL may be connected to a driving voltage supply line (see W11 of FIG. 4), and a second voltage line VSSL may be connected to a common voltage supply line (see W13 of FIG. 4).

The second transistor T2 may be electrically connected to the scan signal line GWL and the data line DL. The scan signal line GWL may be configured to provide a scan signal GW to a gate electrode of the second transistor T2. The second transistor T2 may be configured to transmit, to the first transistor T1, a data signal Dm input from the data line DL, in response to the scan signal GW input from the scan signal line GWL.

The storage capacitor Cst may be electrically connected to the second transistor T2 and the first voltage line VDDL and may be configured to store a voltage corresponding to a difference between a voltage received from the second transistor T2 and a first power supply voltage VDD supplied through the first voltage line VDDL.

The first transistor T1, which acts as a driving transistor, may be configured to control a driving current flowing through the light-emitting element LED. The first transistor T1 may be connected to the first voltage line VDDL and the storage capacitor Cst. The first transistor T1 may be configured to control the driving current flowing from the first voltage line VDDL to the light-emitting element LED according to a voltage value stored in the storage capacitor Cst. The light-emitting element LED may be configured to emit light having a certain luminance according to the driving current. A first electrode of the light-emitting element LED may be electrically connected to the first transistor T1, and a second electrode of the light-emitting element LED may be electrically connected to the second voltage line VSSL configured to supply a second power supply voltage VSS.

FIG. 7A illustrates that the pixel circuit PC includes two transistors and one storage capacitor, but in one or more embodiments, the pixel circuit PC may include three or more transistors.

Referring to FIG. 7B, in one or more embodiments, a pixel circuit PC may include a first transistor T1, a second transistor T2, a third transistor T3, a fourth transistor T4, a fifth transistor T5, a sixth transistor T6, a seventh transistor T7, and a storage capacitor Cst.

The pixel circuit PC may be electrically connected to signal lines and voltage lines. The signal lines may include a data line DL and gate lines, such as a scan signal line GWL, a bypass control line GBL, an initialization control line GIL, and an emission control line EML. The voltage lines may include first and second initialization voltage lines VIL1 and VIL2 and a first voltage line VDDL. In this regard, the first voltage line VDDL may be connected to a driving voltage supply line (see W11 of FIG. 4), and a second voltage line VSSL may be connected to a common voltage supply line (see W13 of FIG. 4) and configured to supply a second power supply voltage VSS.

The first voltage line VDDL may be configured to transmit a first power supply voltage VDD to the first transistor T1. The first initialization voltage line VIL1 may be configured to transmit, to the pixel circuit PC, a first initialization voltage Vint for initializing the first transistor T1. The second initialization voltage line VIL2 may be configured to transmit, to the pixel circuit PC, a second initialization voltage Vaint for initializing a first electrode of a light-emitting element LED.

The first transistor T1 may be electrically connected to the first voltage line VDDL via the fifth transistor T5 and may be electrically connected to the light-emitting element LED via the sixth transistor T6. The first transistor T1, which acts as a driving transistor, may be configured to receive a data signal Dm according to the switching operation of the second transistor T2 and supply a driving current to the light-emitting element LED.

The second transistor T2, which acts as a data write transistor, may be electrically connected to the scan signal line GWL and the data line DL. The second transistor T2 may be electrically connected to the first voltage line VDDL via the fifth transistor T5. The second transistor T2 may be configured to be turned on in response to a scan signal GW received through the scan signal line GWL and perform a switching operation to transmit the data signal Dm received through the data line DL to a first node N1.

The third transistor T3 may be electrically connected to the scan signal line GWL and electrically connected to the light-emitting element LED via the sixth transistor T6. The third transistor T3 may be configured to be turned on in response to the scan signal GW received through the scan signal line GWL and diode-connect the first transistor T1.

The fourth transistor T4, which acts as a first initialization transistor, may be electrically connected to the initialization control line GIL and the first initialization voltage line VIL1. The fourth transistor T4 may be configured to be turned on in response to an initialization control signal GI received through the initialization control line GIL and initialize a voltage of a gate electrode of the first transistor T1 by transmitting the first initialization voltage Vint from the first initialization voltage line VIL1 to the gate electrode of the first transistor T1. The initialization control signal GI may correspond to a scan signal of another pixel circuit arranged in a previous row of the corresponding pixel circuit PC.

The fifth transistor T5 may act as an operation control transistor and the sixth transistor T6 may act as an emission control transistor. The fifth transistor T5 and the sixth transistor T6 may be electrically connected to the emission control line EML and may be configured to be concurrently (e.g., simultaneously) turned on in response to an emission control signal EM received through the emission control line EML and form a current path through which the driving current flows in a direction from the first voltage line VDDL to the light-emitting element LED.

The seventh transistor T7, which acts as a second initialization transistor, may be electrically connected to the bypass control line GBL, the second initialization voltage line VIL2, and the sixth transistor T6. The seventh transistor T7 may be configured to be turned on in response to a bypass control signal GB received through the bypass control line GBL and initialize the first electrode of the light-emitting element LED by transmitting the second initialization voltage Vaint from the second initialization voltage line VIL2 to the first electrode of the light-emitting element LED.

The storage capacitor Cst may include a first electrode CE1 and a second electrode CE2. The first electrode CE1 may be electrically connected to the gate electrode of the first transistor T1 and the second electrode CE2 may be electrically connected to the first voltage line VDDL. The storage capacitor Cst may store and maintain a voltage corresponding to a voltage difference between the first voltage line VDDL and the gate electrode of the first transistor T1, and thus, the voltage applied to the gate electrode of the first transistor T1 may be maintained.

Referring to FIG. 7C, in one or more embodiments, a pixel circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel circuit PC may be electrically connected to signal lines and voltage lines. The signal lines may include a data line DL and gate lines, such as a scan signal line GWL, a bypass control line GBL, an initialization control line GIL, and an emission control line EML. The voltage lines may include first and second initialization voltage lines VIL1 and VIL2, a sustain voltage line VSL, and a first voltage line VDDL. In this regard, the first voltage line VDDL may be connected to a driving voltage supply line (see W11 of FIG. 4), and a second voltage line VSSL may be connected to a common voltage supply line (see W13 of FIG. 4) and configured to supply a second power supply voltage VSS.

The first voltage line VDDL may be configured to transmit a first power supply voltage VDD to the first transistor T1. The first initialization voltage line VIL1 may be configured to transmit, to the pixel circuit PC, a first initialization voltage Vint for initializing the first transistor T1. The second initialization voltage line VIL2 may be configured to transmit, to the pixel circuit PC, a second initialization voltage Vaint for initializing a first electrode of a light-emitting element LED. The sustain voltage line VSL may be configured to provide a sustain voltage VSUS to a second node N2, for example, a second electrode CE2 of the storage capacitor Cst, in an initialization period and a data write period.

The first transistor T1 may be electrically connected to the first voltage line VDDL via the fifth transistor T5 and the eighth transistor T8 and may be electrically connected to the light-emitting element LED via the sixth transistor T6. The first transistor T1, which acts as a driving transistor, may be configured to receive a data signal Dm according to the switching operation of the second transistor T2 and supply a driving current to the light-emitting element LED.

The second transistor T2 may be electrically connected to the scan signal line GWL and the data line DL and electrically connected to the first voltage line VDDL via the fifth transistor T5 and the eighth transistor T8. The second transistor T2 may be configured to be turned on in response to a scan signal GW received through the scan signal line GWL and perform a switching operation to transmit the data signal Dm received through the data line DL to a first node N1.

The third transistor T3 may be electrically connected to the scan signal line GWL and electrically connected to the light-emitting element LED via the sixth transistor T6. The third transistor T3 may be configured to be turned on in response to the scan signal GW received through the scan signal line GWL and compensate for a threshold voltage of the first transistor T1 by diode-connecting the first transistor T1.

The fourth transistor T4 may be electrically connected to the initialization control line GIL and the first initialization voltage line VIL1 and may be configured to be turned on in response to an initialization control signal GI received through the initialization control line GIL and initialize a voltage of a gate electrode of the first transistor T1 by transmitting the first initialization voltage Vint from the first initialization voltage line VIL1 to the gate electrode of the first transistor T1. The initialization control signal GI may correspond to a scan signal of another pixel circuit arranged in a previous row of the corresponding pixel circuit PC.

The fifth transistor T5, the sixth transistor T6, and the eighth transistor T8 may be electrically connected to the emission control line EML and may be configured to be concurrently (e.g., simultaneously) turned on in response to an emission control signal EM received through the emission control line EML and form a current path through which the driving current flows in a direction from the first voltage line VDDL to the light-emitting element LED.

The seventh transistor T7, which acts as a second initialization transistor, may be electrically connected to the bypass control line GBL, the second initialization voltage line VIL2, and the sixth transistor T6. The seventh transistor T7 may be configured to be turned on in response to a bypass control signal GB received through the bypass control line GBL and initialize the first electrode of the light-emitting element LED by transmitting the second initialization voltage Vaint from the second initialization voltage line VIL2 to the first electrode of the light-emitting element LED.

The ninth transistor T9 may be electrically connected to the bypass control line GBL, the second electrode CE2 of the storage capacitor Cst, and the sustain voltage line VSL. The ninth transistor T9 may be configured to be turned on in response to the bypass control signal GB received through the bypass control line GBL and transmit the sustain voltage VSUS to the second node N2, for example, the second electrode CE2 of the storage capacitor Cst, in the initialization period and the data write period.

The eighth transistor T8 and the ninth transistor T9 may be electrically connected to the second node N2, for example, the second electrode CE2 of the storage capacitor Cst. In one or more embodiments, in the initialization period and the data write period, the eighth transistor T8 may be turned off and the ninth transistor T9 may be turned on, and in the emission period, the eighth transistor T8 may be turned on and the ninth transistor T9 may be turned off. Because the sustain voltage VSUS is transmitted to the second node N2 in the initialization period and the data write period, the luminance uniformity (e.g., long range uniformity (LRU)) of the display device according to the voltage drop of the first voltage line VDDL may be improved.

The storage capacitor Cst may include a first electrode CE1 and the second electrode CE2. The first electrode CE1 of the storage capacitor Cst may be electrically connected to the gate electrode of the first transistor T1, and the second electrode CE2 of the storage capacitor Cst may be electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca may store and maintain a voltage corresponding to a voltage difference between the first electrode of the light-emitting element LED and the sustain voltage line VSL while the seventh transistor T7 and the ninth transistor T9 are turned on, and thus, the problem that increases black luminance if (e.g., when) the sixth transistor T6 is turned off may be prevented or reduced.

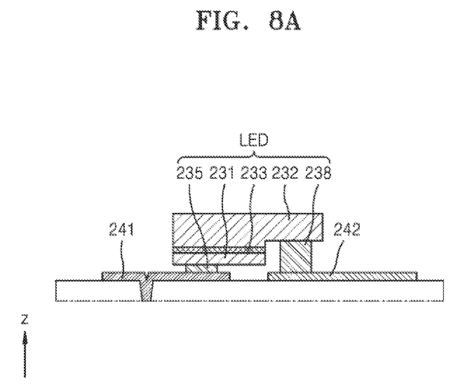

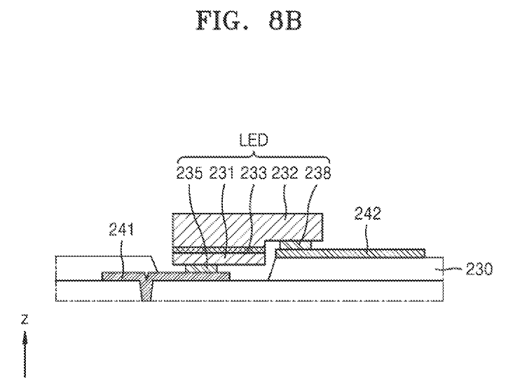

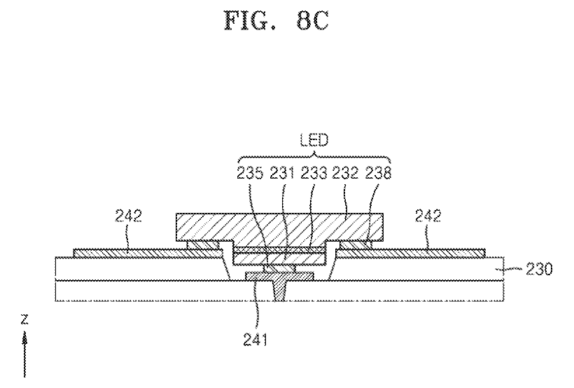

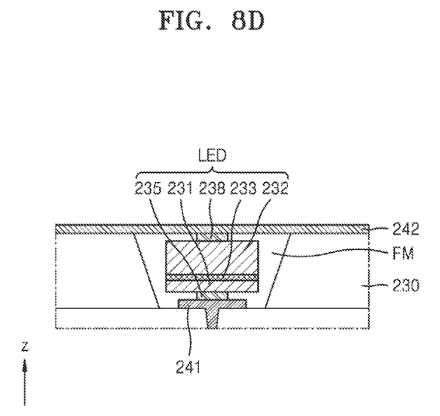

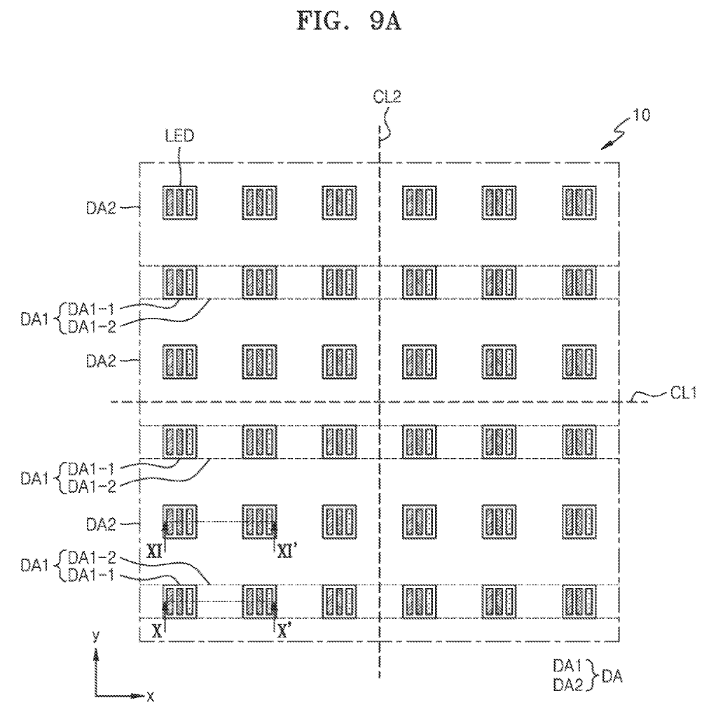

FIGS. 8A to 8D are each a cross-sectional view schematically illustrating a light-emitting element LED of a display panel (see 10 of FIG. 4), according to one or more embodiments of the present disclosure.

Referring to FIG. 8A, in one or more embodiments, the light-emitting element LED may include an inorganic light-emitting element including an inorganic material. The light-emitting element LED may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting element LED may be respectively electrically connected to a first electrode pad 241 and a second electrode pad 242, which are arranged on a same layer. The second electrode pad 242 may be a portion of the second voltage line (see VSSL of FIG. 7A) or may be a conductive layer electrically connected to the second voltage line (see VSSL of FIG. 7A).

In one or more embodiments, the first semiconductor layer 231 may include a p-type (kind) (e.g., P-type) semiconductor layer. The p-type (kind) semiconductor layer may be one or more selected from among semiconductor materials having a composition formula of InₓAl_{y}Ga_{1-x-y}N (0≤x≤1, 0≤y≤1, 0≤x+y≤1), for example, GaN, AlN, AlGaN, InGaN, InN, InAlGaN, or AlInN, and may be doped with a p-type (kind) dopant, such as Mg, Zn, Ca, Sr, or Ba.

The second semiconductor layer 232 may include, for example, an n-type (kind) (e.g., N-type) semiconductor layer. The n-type (kind) semiconductor layer may be one or more selected from among semiconductor materials having a composition formula of InₓAl_{y}Ga_{1-x-y}N (0≤x≤1, 0≤y≤1, 0≤x+y≤1), for example, GaN, AlN, AlGaN, InGaN, InN, InAlGaN, or AlInN, and may be doped with an n-type (kind) dopant, such as Si, Ge, or Sn.

The intermediate layer 233 is an area (e.g., a region) in which electrons and holes recombine. As the electrons and the holes recombine, the intermediate layer 233 may transition to a low energy level to generate light having a wavelength corresponding thereto. For example, in one or more embodiments, the intermediate layer 233 may include a semiconductor material having a composition formula of InₓAl_{y}Ga_{1-x-y}N (0≤x≤1, 0≤y≤1, 0≤x+y≤1), and may have a single quantum well structure or a multi quantum well (MQW) structure. In one or more embodiments, the intermediate layer 233 may have a quantum wire structure or a quantum dot structure.

Although FIG. 8A illustrates that the first semiconductor layer 231 includes a p-type (kind) (e.g., P-type or positive) semiconductor layer and the second semiconductor layer 232 includes an n-type (kind) (e.g., N-type or negative) semiconductor layer, embodiments of the present disclosure are not limited thereto. In one or more embodiments, the first semiconductor layer 231 may include an n-type (kind) (e.g., N-type or negative) semiconductor layer and the second semiconductor layer 232 may include a p-type (kind) (e.g., P-type or positive) semiconductor layer.

Although FIG. 8A illustrates that the first electrode pad 241 and the second electrode pad 242 are arranged on the same layer, embodiments of the present disclosure are not limited thereto. Referring to FIG. 8B, in one or more embodiments, the first electrode pad 241 and the second electrode pad 242 may be arranged on different layers. For example, a bank layer 230 having an opening that overlaps at least a portion of the first electrode pad 241 may be arranged on the first electrode pad 241, and the second electrode pad 242 may be arranged on an upper surface of the bank layer 230. The structure of the light-emitting element LED illustrated in FIG. 8B is the same as described above with reference to FIG. 8A.

In one or more embodiments, as illustrated in FIG. 8C, the second electrode pad 242 may be arranged on both sides (e.g., two opposite sides) of the first electrode pad 241 in a cross-sectional view. The bank layer 230 may include an opening that overlaps at least a portion of the first electrode pad 241, and the second electrode pad 242 may be arranged around the opening of the bank layer 230. In one or more embodiments, in a plan view, the second electrode pad 242 may have a closed loop shape that entirely surrounds the opening of the bank layer 230 and/or the first electrode pad 241. The structure of the light-emitting element LED illustrated in FIG. 8C is the same as described above with reference to FIG. 8A.

Although FIGS. 8A to 8C illustrate that the first electrode 235 and the second electrode 238 of the light-emitting element LED face a same direction (e.g., the upward direction or the +z direction), embodiments of the present disclosure are not limited thereto. As illustrated in FIG. 8D, the first electrode 235 and the second electrode 238 of the light-emitting element LED may face opposite directions.

The bank layer 230 may include an opening that exposes at least a portion of the first electrode pad 241. A thickness of the bank layer 230 may be substantially the same as a thickness of the light-emitting element LED. The opening of the bank layer 230 may be filled with a filling material FM. The second electrode pad 242 may be arranged on an upper surface of the bank layer 230 so as to be electrically connected to (e.g., in contact with) the second electrode 238 of the light-emitting element LED. The filling material FM may be an organic insulating material.

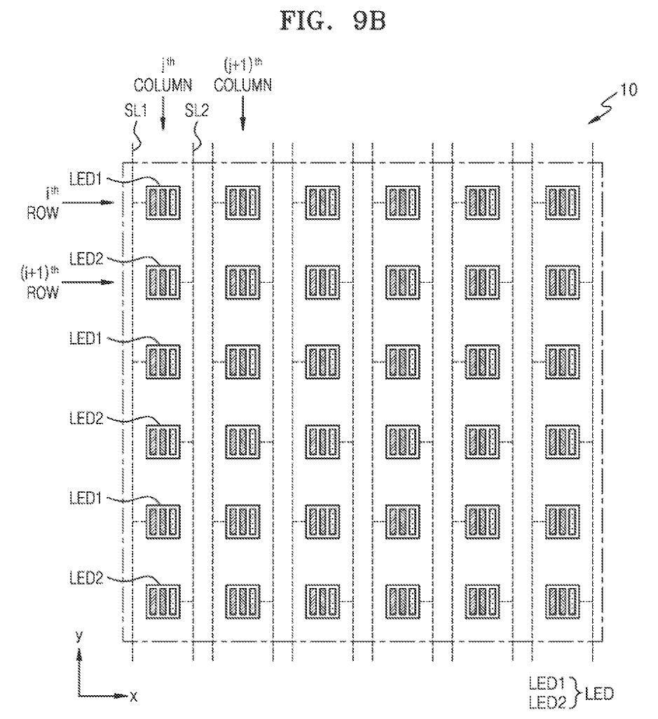

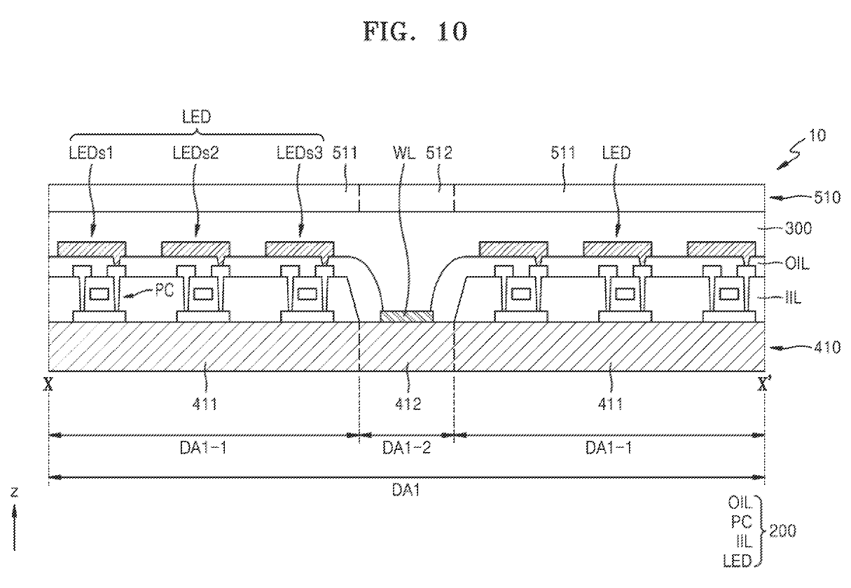

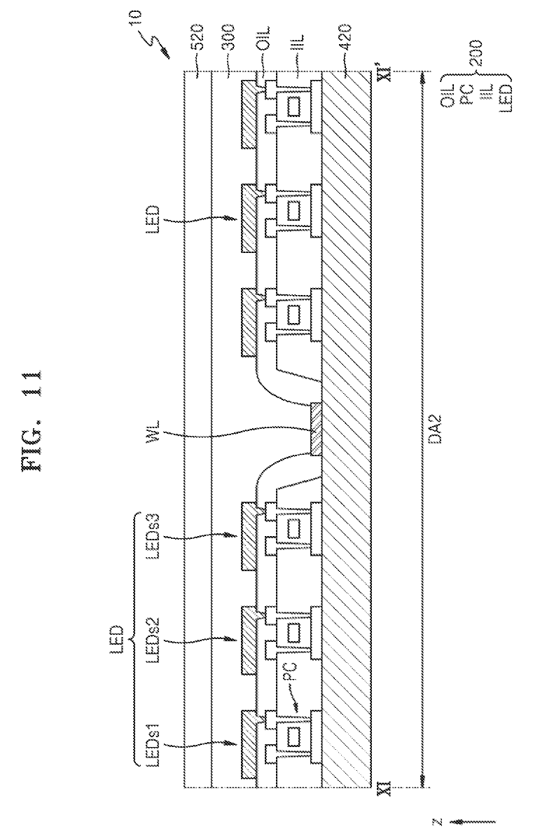

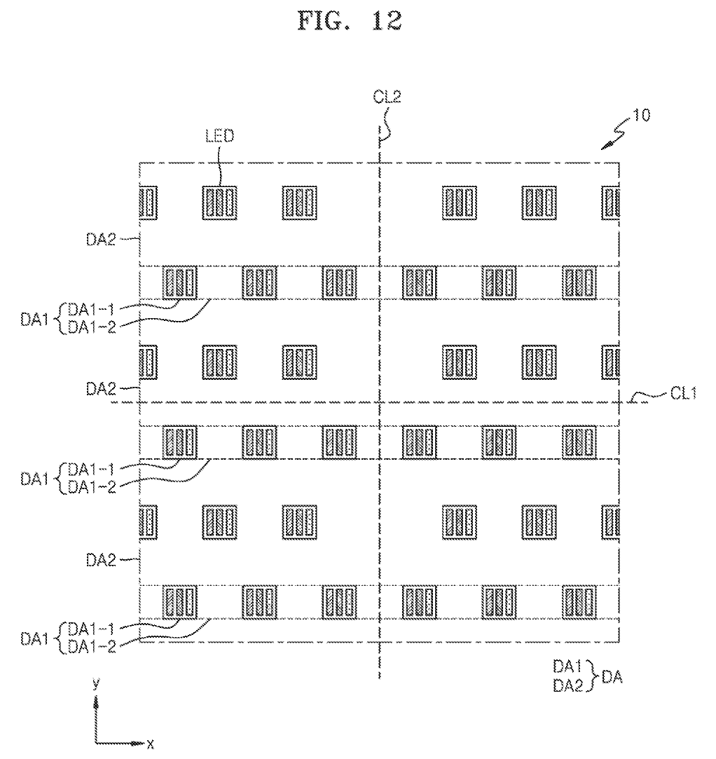

FIG. 9A is a plan view schematically illustrating a display panel 10 according to one or more embodiments of the present disclosure.

For example, FIG. 9A is an enlarged view of region B of FIG. 4 according to one or more embodiments.

Referring to FIG. 9A, in one or more embodiments, a plurality of light-emitting elements LED may be apart (e.g., spaced and/or apart) from one another in a first direction (e.g., the +x direction and/or the -x direction) and a second direction (e.g., the +y direction and/or the -y direction). The plurality of light-emitting elements LED may be arranged in a grid form. In a plan view, the plurality of light-emitting elements LED may be arranged along a plurality of rows and a plurality of columns. The plurality of light-emitting elements LEDs may be symmetrically arranged with respect to a first center line CL1 and a second center line CL2. The plurality of light-emitting elements LED may be apart (e.g., spaced and/or apart) from the first center line CL1 and the second center line CL2. For example, the plurality of light-emitting elements LED may be arranged at equal intervals from each other in the first direction (e.g., the +x direction and/or the -x direction). For example, the plurality of light-emitting elements LED may be arranged at equal intervals from each other in the second direction (e.g., the +y direction and/or the -y direction). However, this is merely an example and the layout of the plurality of light-emitting elements LED is not limited thereto.

The display area DA may be divided into a plurality of first display areas DA1 and a plurality of second display areas DA2. For example, the display area DA may include the plurality of first display areas DA1 and the plurality of second display areas DA2.

The plurality of first display areas DA1 may each extend in the first direction (e.g., the +x direction and/or the -x direction) and may overlap the plurality of light-emitting elements LED arranged in the first direction (e.g., the +x direction and/or the -x direction). The plurality of first display areas DA1 may be apart (e.g., spaced and/or apart) from one another in the second direction (e.g., the +y direction and/or the -y direction). A length of each of the plurality of first display areas DA1 in the second direction (e.g., the +y direction and/or the -y direction) may be equal to a length of each of the plurality of light-emitting elements LED in the second direction (e.g., the +y direction and/or the -y direction). For example, the plurality of first display areas DA1 may be arranged at equal intervals from each other in the second direction (e.g., the +y direction and/or the -y direction).

The plurality of second display areas DA2 may each extend in the first direction (e.g., the +x direction and/or the -x direction) and may overlap the plurality of light-emitting elements LED arranged in the first direction (e.g., the +x direction and/or the -x direction). The plurality of second display areas DA2 may be apart (e.g., spaced and/or apart) from one another in the second direction (e.g., the +y direction and/or the -y direction). A length of each of the plurality of second display areas DA2 in the second direction (e.g., the +y direction and/or the -y direction) may be greater than the length of each of the plurality of light-emitting elements LED in the second direction (e.g., the +y direction and/or the -y direction). For example, the plurality of second display areas DA2 may be arranged at equal intervals from each other in the second direction (e.g., the +y direction and/or the -y direction).

The plurality of second display areas DA2 may each be arranged between two first display areas DA1 adjacent to each other among the plurality of first display areas DA1. In a plan view, one second display area DA2 may be arranged between two first display areas DA1 adjacent to each other. The plurality of first display areas DA1 and the plurality of second display areas DA2 may be alternately arranged in the second direction (e.g., the +y direction and/or the -y direction).

The plurality of first display areas DA1 may be respectively divided into a plurality of first-first display areas DA1-1 and a plurality of first-second display areas DA1-2. For example, the plurality of first display areas DA1 may respectively include the plurality of first-first display areas DA1-1 and the plurality of first-second display areas DA1-2. For example, the plurality of first display areas DA1 may each be respectively divided into the plurality of first-first display areas DA1-1 and the plurality of first-second display areas DA1-2. For example, the plurality of first display areas DA1 may each respectively include the plurality of first-first display areas DA1-1 and the plurality of first-second display areas DA1-2.

The plurality of first-first display areas DA1-1 may overlap the plurality of light-emitting elements LED. A length of each of the plurality of first-first display areas DA1-1 in the second direction (e.g., the +y direction and/or the -y direction) may be equal to the length of each of the plurality of light-emitting elements LED in the second direction (e.g., the +y direction and/or the -y direction). The plurality of first-second display areas DA1-2 may be arranged between the plurality of first-first display areas

DA1-1. For example, each of the plurality of first-second display areas DA1-2 may be arranged between two neighboring first-first display areas DA1-1. A length of each of the plurality of first-second display areas DA1-2 in the first direction (e.g., the +x direction and/or the -x direction) may be equal to the distance between two light-emitting elements LED arranged adjacent to each other in the first direction (e.g., the +x direction and/or the -x direction). The plurality of first-first display areas DA1-1 and the plurality of first-second display areas DA1-2 may be alternately arranged in the first direction (e.g., the +x direction and/or the -x direction).

FIG. 9B is a plan view schematically illustrating a display panel 10 according to one or more embodiments of the present disclosure.

For example, FIG. 9B is an enlarged view of region B of FIG. 4 according to one or more embodiments.

Referring to FIG. 9B, in one or more embodiments, the plurality of light-emitting elements LED may include a plurality of first light-emitting elements LED1 and a plurality of second light-emitting elements LED2 arranged in a same column. For example, a plurality of light-emitting elements LED arranged in a j^{th} column may be divided into a plurality of first light-emitting elements LED1 and a plurality of second light-emitting elements LED2.

The plurality of first light-emitting elements LED1 may be electrically connected to a first signal line SL1. For example, the plurality of first light-emitting elements LED1 may be electrically connected to a same signal line. In addition, the plurality of second light-emitting elements LED2 may be electrically connected to a second signal line SL2. For example, the plurality of second light-emitting elements LED2 may be electrically connected to a same signal line. The first signal line SL1 and the second signal line SL2 may be different signal lines. For example, the plurality of first light-emitting elements LED1 and the plurality of second light-emitting elements LED2 may be configured to receive different signals. For example, the first signal line SL1 and the second signal line SL2 may each include at least one of a data line (see DL of FIG. 7A) or a scan signal line (see GWL of FIG. 7A).

For example, in one or more embodiments, the plurality of first light-emitting elements LED1 and the plurality of second light-emitting elements LED2 may be respectively and alternately arranged in the second direction (e.g., the +y direction and/or the -y direction). For example, one of the plurality of first light-emitting elements LED1 may be arranged in an i^{th} row, and one of the plurality of second light-emitting elements LED2 may be arranged in a (i+1)^{th} row.

For convenience of explanation, the plurality of light-emitting elements LEDs arranged in the j^{th} column are described as an example, but the same may also be applied to the plurality of light-emitting elements LED arranged in other columns. For example, the same connection relationship of the signal lines described above may be applied to the plurality of light-emitting elements LED arranged in a (j+1)^{th} column.

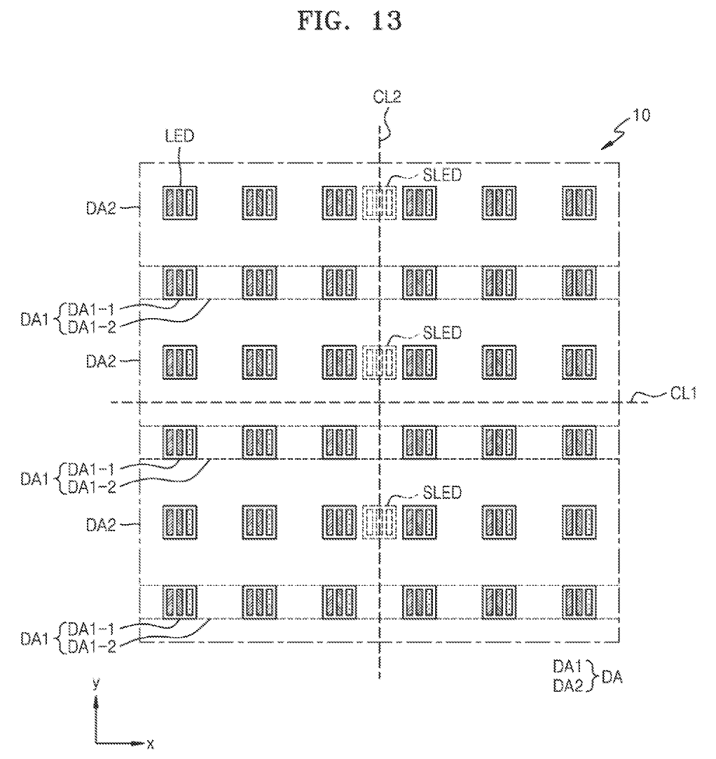

FIG. 10 and FIG. 11 are each a cross-sectional view schematically illustrating a portion of the display panel 10 according to one or more embodiments of the present disclosure.

For example, FIG. 10 is a cross-sectional view of the display panel 10 of FIG. 9A taken along the line X-X' of FIG. 9A, and FIG. 11 is a cross-sectional view of the display panel 10 of FIG. 9A taken along the line XI-XI' of FIG. 9A.

In FIG. 10 and FIG. 11, the same reference numerals as those in FIG. 6 denote the same members, and redundant descriptions thereof are not provided for conciseness.

Referring to FIGS. 6, 9A, 9B, 10, and 11, the substrate (see 400 of FIG. 6) may be divided into a plurality of first substrate portions 410 and a plurality of second substrate portions 420. For example, the substrate (see 400 of FIG. 6) may include the plurality of first substrate portions 410 and the plurality of second substrate portions 420. The plurality of first substrate portions 410 may overlap the plurality of first display

areas DA1. The plurality of second substrate portions 420 may overlap the plurality of second display areas DA2. The plurality of first substrate portions 410 and the plurality of second substrate portions 420 may be respectively and alternately arranged in the second direction (e.g., the +y direction and/or the -y direction). For example, the plurality of first substrate portions 410 may be alternately arranged with one another in the second direction with the second substrate portion 420 interposed therebetween (e.g., the +y direction and/or the -y direction), and the plurality of second substrate portions 420 may be alternately arranged with one another in the second direction with the first substrate portion 410 interposed therebetween (e.g., the +y direction and/or the -y direction)..

The plurality of first substrate portions 410 may each be divided into a plurality of first-first substrate portions 411 and a plurality of first-second substrate portions 412. For example, the plurality of first substrate portions 410 may respectively include the plurality of first-first substrate portions 411 and the plurality of first-second substrate portions 412. The plurality of first-first substrate portions 411 may overlap the plurality of first-first display areas DA1. The plurality of first-first substrate portions 411 may overlap the plurality of light-emitting elements LED. The plurality of first-second substrate portions 412 may overlap the plurality of first-second display areas DA1-2. The plurality of first-second substrate portions 412 may be arranged between the plurality of first-first substrate portions 411. For example, the first-second substrate portions 412 may be arranged between two neighboring first-first substrates 411. The plurality of first-first substrate portions 411 and the plurality of first-second substrate portions 412 may be alternately arranged in the first direction (e.g., the +x direction and/or the -x direction).

The encapsulation portion 500 may be divided into a plurality of first encapsulation portions 510 and a plurality of second encapsulation portions 520. For example, the encapsulation portion 500 may include the plurality of first encapsulation

portions 510 and the plurality of second encapsulation portions 520. The plurality of first encapsulation portions 510 may overlap the plurality of first display areas DA1. The plurality of second encapsulation portions 520 may overlap the plurality of second display areas DA2. The plurality of first encapsulation portions 510 and the plurality of second encapsulation portions 520 may be alternately arranged in the second direction (e.g., the +y direction and/or the -y direction).

The plurality of first encapsulation portions 510 may each be divided into a plurality of first-first encapsulation portions 511 and a plurality of first-second encapsulation portions 512. For example, the plurality of first encapsulation portions 510 may respectively include the plurality of first-first encapsulation portions 511 and the plurality of first-second encapsulation portions 512. The plurality of first-first encapsulation portions 511 may overlap the plurality of first-first display areas DA1. The plurality of first-first encapsulation portions 511 may overlap the plurality of light-emitting elements LED. The plurality of first-second encapsulation portions 512 may overlap the plurality of first-second display areas DA1-2. The plurality of first-second encapsulation portions 512 may be arranged between the plurality of first-first encapsulation portions 511. For example, the first-second encapsulation portion 512 may be arranged between two neighboring first-first encapsulation portion 511. The plurality of first-first encapsulation portions 511 and the plurality of first-second encapsulation portions 512 may be alternately arranged in the first direction (e.g., the +x direction and/or the -x direction).

The first substrate portion 410 may overlap the first encapsulation portion 510. For example, the first-first substrate portion 411 may overlap the first-first encapsulation portion 511, and the first-second substrate portion 412 may overlap the first-second encapsulation portion 512. In addition, the second substrate portion 420 may overlap the second encapsulation portion 520.

In one or more embodiments, in the display panel 10, a modulus of the first display area DA1 may be greater than a modulus of the second display area DA2.

For example, the modulus of at least one of (e.g., at least one selected from among) the plurality of first substrate portions 410 may be greater than the modulus of at least one of (e.g., at least one selected from among) the plurality of second substrate portions 420. For example, in one or more embodiments, the modulus of each of the plurality of first substrate portions 410 may be greater than the modulus of each of the plurality of second substrate portions 420. The modulus of the substrate 400 may be controlled or selected by a process of curing the substrate 400.

For example, a modulus of at least one of (e.g., at least one selected from among) the plurality of first encapsulation portions 510 may be greater than a modulus of at least one of (e.g., at least one selected from among) the plurality of second encapsulation portions 520. For example, in one or more embodiments, the modulus of each of the plurality of first encapsulation portions 510 may be greater than the modulus of each of the plurality of second encapsulation portions 520. The modulus of the encapsulation portion 500 may be controlled or selected by a process of curing the encapsulation portion 500.

For example, the modulus of at least one of (e.g., at least one selected from among) the plurality of first-second substrate portions 412 may be greater than the modulus of at least one of (e.g., at least one selected from among) the plurality of second substrate portions 420. For example, in one or more embodiments, the modulus of each of the plurality of first-second substrate portions 412 may be greater than the modulus of each of the plurality of second substrate portions 420.

For example, the modulus of at least one of (e.g., at least one selected from among) the plurality of first-second encapsulation portions 512 may be greater than the modulus of at least one of (e.g., at least one selected from among) the plurality of second encapsulation portions 520. For example, in one or more embodiments, the

modulus of each of the plurality of first-second encapsulation portions 512 may be greater than the modulus of each of the plurality of second encapsulation portions 520.

For example, the modulus of at least one of (e.g., at least one selected from among) the plurality of first-second substrate portions 412 may be equal to the modulus of at least one of (e.g., at least one selected from among) the plurality of first-first substrate portions 411. For example, in one or more embodiments, the modulus of each of the plurality of first-first substrate portions 411 may be equal to the modulus of each of the plurality of first-second substrate portions 412.

For example, the modulus of at least one of (e.g., at least one selected from among) the plurality of first-second encapsulation portions 512 may be equal to the modulus of at least one of (e.g., at least one selected from among) the plurality of first-first encapsulation portions 511. For example, in one or more embodiments, the modulus of each of the plurality of first-first encapsulation portions 511 may be equal to the modulus of each of the plurality of first-second encapsulation portions 512.

FIG. 12 is a plan view schematically illustrating the display panel 10 according to one or more embodiments.

For example, FIG. 9A is an enlarged view of region B of FIG. 4 before the display panel 10 is stretched, and FIG. 12 is an enlarged view of region B of FIG. 4 after the display panel 10 is stretched.

Referring to FIG. 9A and FIG. 12, as the display panel 10 is stretched in the first direction (e.g., the +x direction and/or in the -x direction), the distance between the plurality of light-emitting elements LED in the first direction (e.g., the +x direction and/or the -x direction) may increase, for example, the distance between light-emitting elements LED among the plurality of light-emitting elements LED in the first direction may increase. For example, the distance between respective light-emitting elements (LED) among the plurality of light-emitting elements (LED) in the first direction may increase.

The elongation of the display panel 10 may be the greatest at the center of the display panel 10. For example, if (e.g., when) the display panel 10 is stretched, the distance between the plurality of light-emitting elements LED may increase as the distance to the second center line CL2 decreases.

In one or more embodiments, the modulus in the first display area DA1 may be greater than the modulus in the second display area DA2. In one or more embodiments, the modulus in the first-second display area DA1-2 may be greater than the modulus in the second display area DA2. In such a structure, even if (e.g., when) the display panel 10 is stretched, the elongation of the first display area DA1 may be less than the elongation of the second display area DA2. Therefore, during the stretching process of the display panel 10, the resolution degradation due to non-uniform positional changes of the plurality of light-emitting elements LED may be reduced.

Referring to FIGS. 9B and 12, as the display panel 10 is stretched in the first direction (e.g., the +x direction and/or the -x direction), the number of columns of light-emitting elements LED may increase. For example, as illustrated in FIG. 9B, before the display panel 10 is stretched, the plurality of light-emitting elements LED may be arranged in six columns. As illustrated in FIG. 12, after the display panel 10 is stretched, the plurality of light-emitting elements LED may be arranged in 12 columns. For example, after the display panel 10 is stretched, the plurality of first light-emitting elements LED1 and the plurality of second light-emitting elements LED2 may be arranged in different columns.

In such a structure, the first signal line SL1 and the second signal line SL2 may be configured to transmit signals to the plurality of light-emitting elements LED arranged in different columns. Even if (e.g., when) the display panel 10 is stretched, the deformation of the layout of the plurality of light-emitting elements LED may be

compensated for as different signal lines are connected to the plurality of light-emitting elements LED arranged in different columns.

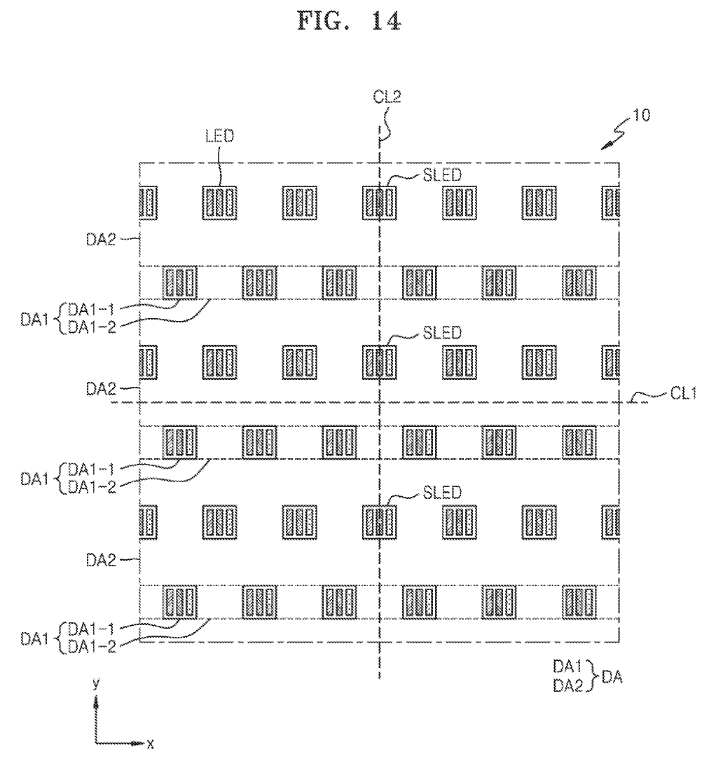

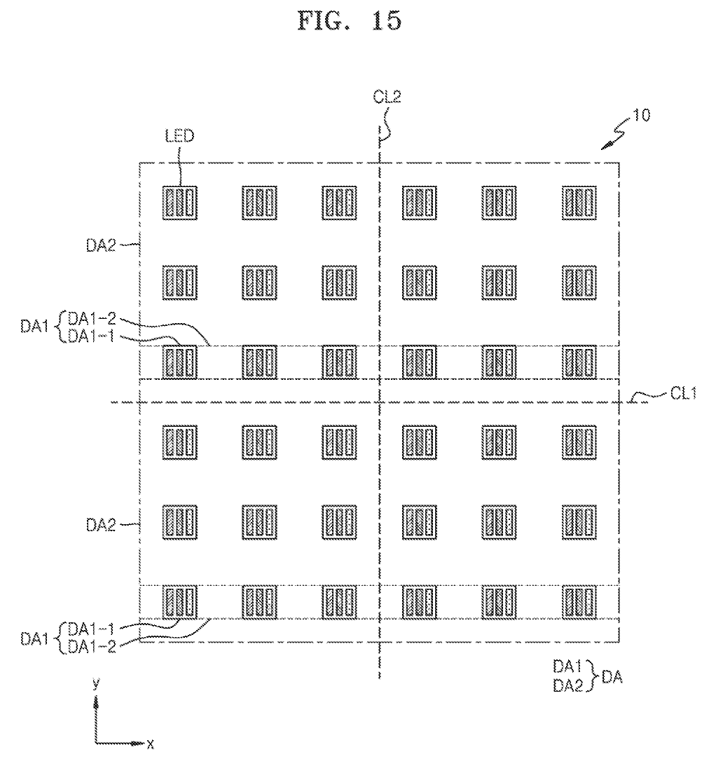

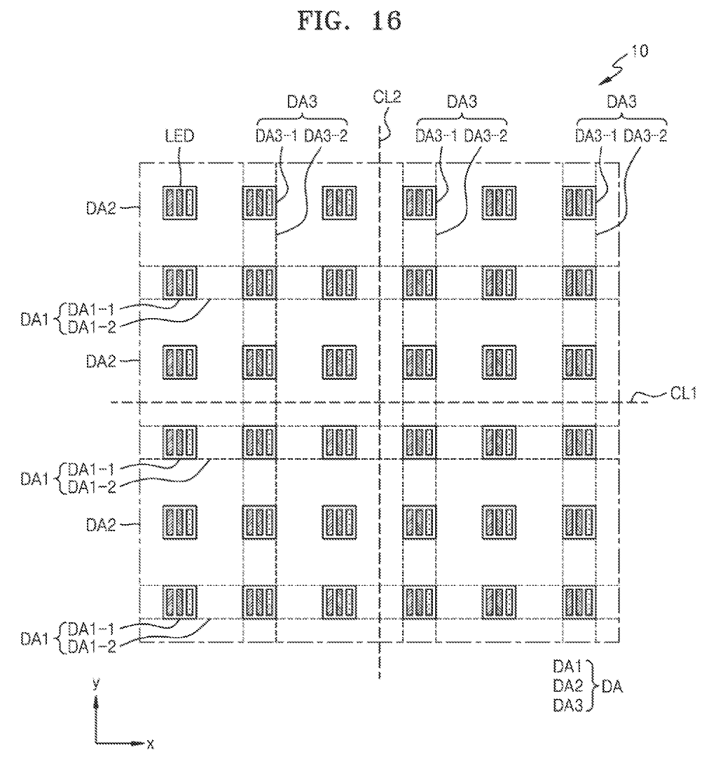

FIG. 13 and FIG. 14 are each a plan view schematically illustrating the display panel 10 according to one or more embodiments of the present disclosure.

For example, FIG. 13 is an enlarged view of region B of FIG. 4 before the display panel 10 is stretched, and FIG. 14 is an enlarged view of region B of FIG. 4 after the display panel 10 is stretched.

Referring to FIG. 13 and FIG. 14, the display panel 10 may include an auxiliary light-emitting element SLED.

The auxiliary light-emitting element SLED may have the same structure as the light-emitting element LED described above with reference to FIG. 5 and FIG. 6. The auxiliary light-emitting element SLED may be electrically connected to a corresponding pixel circuit. The auxiliary light-emitting element SLED may include three sub-light-emitting elements LED configured to externally emit light of different colors.

The auxiliary light-emitting element SLED may be arranged between two light-emitting elements LED adjacent to each other among the plurality of light-emitting elements LED. The auxiliary light-emitting element SLED may be arranged in at least one of (e.g., at least one selected from among) the plurality of second display areas DA2. In one or more embodiments, the auxiliary light-emitting element SLED may be arranged to overlap the second center line CL2.

For example, a plurality of auxiliary light-emitting elements SLED may be provided. The plurality of auxiliary light-emitting element SLED may be respectively arranged in the plurality of second display areas DA2. The plurality of auxiliary light-emitting elements SLED may be apart (e.g., spaced and/or apart) from one another in the second direction (e.g., the +y direction and/or the -y direction) so as to overlap the second center line CL2.

The auxiliary light-emitting element SLED may be turned on if (e.g., when) the display panel 10 is stretched in the first direction (e.g., the +x direction and/or the -x direction) and may be turned off if (e.g., when) the display panel 10 is compressed in the first direction (e.g., the +x direction and/or the -x direction). For example, as illustrated in FIG. 13, the auxiliary light-emitting element SLED may be turned off before the display panel 10 is stretched. For example, as illustrated in FIG. 14, the auxiliary light-emitting element SLED may be turned on after the display panel 10 is stretched.

In such a structure, before the display panel 10 illustrated in FIG. 13 is stretched, the plurality of light-emitting elements LED may be arranged at relatively equal intervals from each other and the auxiliary light-emitting elements SLED may be turned off. In addition, after the display panel 10 illustrated in FIG. 14 is stretched, the auxiliary light-emitting element SLED arranged at the center where the gap between the plurality of light-emitting elements LED is the greatest may be turned on. Therefore, the resolution of the display panel 10 may be substantially uniform both before and after the display panel 10 is stretched.

FIG. 15 is a plan view schematically illustrating the display panel 10 according to one or more embodiments of the present disclosure.

For example, FIG. 15 is an enlarged view of region B of FIG. 4 according to one or more embodiments.

Referring to FIG. 15, the display area DA may include the plurality of first display areas DA1 and the plurality of second display areas DA2. The plurality of first display areas DA1 may each include a plurality of first-first display areas DA1-1 and a plurality of first-second display areas DA1-2.

The plurality of first display areas DA1 may each extend in the first direction (e.g., the +x direction and/or the -x direction) and may overlap the plurality of light-emitting elements LED arranged in the first direction (e.g., the +x direction and/or the -x

direction). The plurality of first display areas DA1 may be apart (e.g., spaced and/or apart) from one another in the second direction (e.g., the +y direction and/or the -y direction). The plurality of second display areas DA2 may each extend in the first direction (e.g., the +x direction and/or the -x direction) and may overlap the plurality of light-emitting elements LED arranged in the first direction (e.g., the +x direction and/or the -x direction). The plurality of second display areas DA2 may be apart (e.g., spaced and/or apart) from one another in the second direction (e.g., the +y direction and/or the -y direction).

As illustrated in FIG. 15, in one or more embodiments, the plurality of light-emitting elements LED constituting one row in the first direction (e.g., the x direction and/or the -x direction) may be arranged in one first display area DA1. In addition, the plurality of light-emitting elements LED constituting two rows in the first direction (e.g., the x direction and/or the -x direction) may be arranged in one second display area DA2.

However, this is merely an example, and the layout of each of the first display area DA1 and the second display area DA2 is not limited thereto. For example, in one or more embodiments, the plurality of light-emitting elements LED constituting two rows in the first direction (e.g., the x direction and/or the -x direction) may be arranged in one first display area DA1. In addition, the plurality of light-emitting elements LED constituting one row in the first direction (e.g., the x direction and/or the -x direction) may be arranged in one second display area DA2. In one or more embodiments, for example, the plurality of light-emitting elements LED constituting a plurality of rows in the first direction (e.g., the +x direction and/or the -x direction) may be arranged in each of one first display area DA1 and one second display area DA2.

FIG. 16 is a plan view schematically illustrating the display panel 10 according to one or more embodiments of the present disclosure.

For example, FIG. 16 is an enlarged view of region B of FIG. 4 according to one or more embodiments.

According to one or more embodiments of the present disclosure, the display area DA may be divided into a plurality of first display areas DA1, a plurality of second display areas DA2, and a plurality of third display areas DA3. For example, the display area DA may include the plurality of first display areas DA1, the plurality of second display areas DA2, and the plurality of third display areas DA3.

The plurality of first display areas DA1 may each extend in the first direction (e.g., the +x direction and/or the -x direction) and may overlap the plurality of light-emitting elements LED arranged in the first direction (e.g., the +x direction and/or the -x direction). The plurality of first display areas DA1 may be apart (e.g., spaced and/or apart) from one another in the second direction (e.g., the +y direction and/or the -y direction). A length of each of the plurality of first display areas DA1 in the second direction (e.g., the +y direction and/or the -y direction) may be equal to a length of each of the plurality of light-emitting elements LED in the second direction (e.g., the +y direction and/or the -y direction). For example, the plurality of first display areas DA1 may be arranged at equal intervals from each other in the second direction (e.g., the +y direction and/or the -y direction).

The plurality of third display areas DA3 may each extend in the second direction (e.g., the +y direction and/or the -y direction) and may overlap the plurality of light-emitting elements LED arranged in the second direction (e.g., the +y direction and/or the -y direction). The plurality of third display areas DA3 may be apart (e.g., spaced and/or apart) from one another in the first direction (e.g., the +x direction and/or the -x direction). A length of each of the plurality of third display areas DA3 in the first direction (e.g., the +x direction and/or the -x direction) may be equal to a length of each of the plurality of light-emitting elements LED in the first direction (e.g., the +x direction and/or the -x direction). For example, the plurality of third display areas DA3 may be

arranged at equal intervals from each other in the first direction (e.g., the +x direction and/or the -x direction).

The plurality of second display areas DA2 may be respectively arranged between the plurality of first display areas DA1 and the plurality of third display areas DA3. Each of the plurality of second display areas DA2 may be surrounded by one or more of the plurality of first display areas DA1 and one or more of the plurality of third display areas DA3. The plurality of second display areas DA2 may be apart (e.g., spaced and/or apart) from one another in the first direction (e.g., the +x direction and/or the -x direction) and the second direction (e.g., the +y direction and/or the -y direction). a length of each of the plurality of second display areas DA2 in the first direction (e.g., the +x direction and/or the -x direction) may be greater than the length of each of the plurality of light-emitting elements LED in the first direction (e.g., the +x direction and/or the -x direction). A length of each of the plurality of second display areas DA2 in the second direction (e.g., the +y direction and/or the -y direction) may be greater than the length of each of the plurality of light-emitting elements LED in the second direction (e.g., the +y direction and/or the -y direction). For example, the plurality of second display areas DA2 may be arranged at equal intervals from one another in the first direction (e.g., the +x direction and/or the -x direction) and the second direction (e.g., the +y direction and/or the -y direction).

The plurality of second display areas DA2 may each be arranged between two first display areas DA1 adjacent to each other among the plurality of first display areas DA1. In a plan view, one second display area DA2 may be arranged between two first display areas DA1 adjacent to each other. The plurality of first display areas DA1 and the plurality of second display areas DA2 may be alternately arranged in the second direction (e.g., the +y direction and/or the -y direction).

The plurality of second display areas DA2 may each be arranged between two third display areas DA3 adjacent to each other among the plurality of third display

areas DA3. In a plan view, one second display area DA2 may be arranged between two third display areas DA3 adjacent to each other. The plurality of third display areas DA3 and the plurality of second display areas DA2 may be alternately arranged in the first direction (e.g., the +x direction and/or the -x direction).

The plurality of first display areas DA1 may be respectively divided into a plurality of first-first display areas DA1-1 and a plurality of first-second display areas DA1-2. For example, the plurality of first display areas DA1 may respectively include the plurality of first-first display areas DA1-1 and the plurality of first-second display areas DA1-2. For example, the plurality of first display areas DA1 may each be respectively divided into the plurality of first-first display areas DA1-1 and the plurality of first-second display areas DA1-2. For example, the plurality of first display areas DA1 may each respectively include the plurality of first-first display areas DA1-1 and the plurality of first-second display areas DA1-2.

The plurality of first-first display areas DA1-1 may overlap the plurality of light-emitting elements LED. A length of each of the plurality of first-first display areas DA1-1 in the second direction (e.g., the +y direction and/or the -y direction) may be equal to the length of each of the plurality of light-emitting elements LED in the second direction (e.g., the +y direction and/or the -y direction). The plurality of first-second display areas DA1-2 may be arranged between the plurality of first-first display areas DA1-1. For example, the first-second display area DA1-2 may be arranged between two neighboring first-first display areas DA1-1. A length of each of the plurality of first-second display areas DA1-2 in the first direction (e.g., the +x direction and/or the -x direction) may be equal to the distance between two light-emitting elements LED arranged adjacent to each other in the first direction (e.g., the +x direction and/or the -x direction). The plurality of first-first display areas DA1-1 and the plurality of first-second display areas DA1-2 may be alternately arranged in the first direction (e.g., the +x direction and/or the -x direction).

The plurality of third display areas DA3 may be respectively divided into a plurality of third-first display areas DA3-1 and a plurality of third-second display areas DA3-2. For example, the plurality of third display areas DA3 may respectively include the plurality of third-first display areas DA3-1 and the plurality of third-second display areas DA3-2. For example, the plurality of third display areas DA3 may each be respectively divided into the plurality of third-first display areas DA3-1 and the plurality of third-second display areas DA3-2. For example, the plurality of third display areas DA3 may each respectively include the plurality of third-first display areas DA3-1 and the plurality of third-second display areas DA3-2

The plurality of third-first display areas DA3-1 may overlap the plurality of light-emitting elements LED. A length of each of the plurality of third-first display areas DA3-1 in the first direction (e.g., the +x direction and/or the -x direction) may be equal to the length of each of the plurality of light-emitting elements LED in the first direction (e.g., the +x direction and/or the -x direction). The plurality of third-second display areas DA3-2 may be arranged between the plurality of third-first display areas DA3-1. For example, the third-second display area DA3-2 may be arranged between two neighboring third-first display areas DA3-1. A length of each of the plurality of third-second display areas DA3-2 in the second direction (e.g., the +y direction and/or the -y direction) may be equal to the distance between two light-emitting elements LED arranged adjacent to each other in the second direction (e.g., the +y direction and/or the -y direction). The plurality of third-first display areas DA3-1 and the plurality of third-second display areas DA3-2 may be alternately arranged in the second direction (e.g., the +y direction and/or the -y direction).

The substrate (see 400 of FIG. 6) may be divided into a plurality of first substrate portions (see 410 of FIG. 10), a plurality of second substrate portions (see 420 of FIG. 11), and a plurality of third substrate portions. For example, the substrate (see 400 of FIG. 6) may include the plurality of first substrate portions (see 410 of FIG. 10),

the plurality of second substrate portions (see 420 of FIG. 11), and the plurality of third substrate portions. The plurality of first substrate portions (see 410 of FIG. 10) may overlap the plurality of first display areas DA1. The plurality of second substrate portions (see 420 of FIG. 11) may overlap the plurality of second display areas DA2. The plurality of third substrate portions may overlap the plurality of third display areas DA3.

The plurality of first substrate portions (see 410 of FIG. 10) may each be divided into a plurality of first-first substrate portions (see 411 of FIG. 10) and a plurality of first-second substrate portions (see 412 of FIG. 10). For example, the plurality of first substrate portions (see 410 of FIG. 10) may each respectively include the plurality of first-first substrate portions (see 411 of FIG. 10) and the plurality of first-second substrate portions (see 412 of FIG. 10). The plurality of first-first substrate portions (see 411 of FIG. 10) may overlap the plurality of first-first display areas DA1. The plurality of first-first substrate portions (see 411 of FIG. 10) may overlap the plurality of light-emitting elements LED. The plurality of first-second substrate portions (see 412 of FIG. 10) may overlap the plurality of first-second display areas DA1-2. The plurality of first-second substrate portions (see 412 of FIG. 10) may be arranged between the plurality of first-first substrate portions (see 411 of FIG. 10). For example, the first-second substrate portion may be arranged between two neighboring first-first substrate portions. The plurality of first-first substrate portions (see 411 of FIG. 10) and the plurality of first-second substrate portions (see 412 of FIG. 10) may be alternately arranged in the first direction (e.g., the +x direction and/or the -x direction).

The plurality of third substrate portions may each be divided into a plurality of third-first substrate portions and a plurality of third-second substrate portions. For example, the plurality of third substrate portions may each respectively include the plurality of third-first substrate portions and the plurality of third-second substrate portions. The plurality of third-first substrate portions may overlap the plurality of third-

first display areas DA3-1. The plurality of third-first substrate portions may overlap the plurality of light-emitting elements LED. The plurality of third-second substrate portions may overlap the plurality of third-second display areas DA3-2. The plurality of third-second substrate portions may be arranged between the plurality of third-first substrate portions. For example, the third-second substrate portion may be arranged between two neighboring third-first substrate portions. The plurality of third-first substrate portions and the plurality of third-second substrate portions may be alternately arranged in the second direction (e.g., the +y direction and/or the -y direction).

The encapsulation portion (see 500 of FIG. 6) may be divided into a plurality of first encapsulation portions (see 510 of FIG. 10), a plurality of second encapsulation portions (see 520 of FIG. 11), and a plurality of third encapsulation portions. For example, the encapsulation portion (see 500 of FIG. 6) may include the plurality of first encapsulation portions (see 510 of FIG. 10), the plurality of second encapsulation portions (see 520 of FIG. 11), and the plurality of third encapsulation portions. The plurality of first encapsulation portions (see 510 of FIG. 10) may overlap the plurality of first display areas DA1. The plurality of second encapsulation portions (see 520 of FIG. 11) may overlap the plurality of second display areas DA2. The plurality of third encapsulation portions may overlap the plurality of third display areas DA3.

The plurality of first encapsulation portions (see 510 of FIG. 10) may each be divided into a plurality of first-first encapsulation portions (see 511 of FIG. 10) and a plurality of first-second encapsulation portions (see 512 of FIG. 10). For example, the plurality of first encapsulation portions (see 510 of FIG. 10) may each respectively include the plurality of first-first encapsulation portions (see 511 of FIG. 10) and the plurality of first-second encapsulation portions (see 512 of FIG. 10). The plurality of first-first encapsulation portions (see 511 of FIG. 10) may overlap the plurality of first-first display areas DA1. The plurality of first-first encapsulation portions (see 511 of FIG. 10) may overlap the plurality of light-emitting elements LED. The plurality of first-

second encapsulation portions (see 512 of FIG. 10) may overlap the plurality of first-second display areas DA1-2. The plurality of first-second encapsulation portions (see 512 of FIG. 10) may be arranged between the plurality of first-first encapsulation portions (see 511 of FIG. 10). For example, the first-second encapsulation portion may be arranged between two neighboring first-first encapsulation portions. The plurality of first-first substrate portions (see 511 of FIG. 10) and the plurality of first-second encapsulation portions (see 512 of FIG. 10) may be alternately arranged in the first direction (e.g., the +x direction and/or the -x direction).

The plurality of third encapsulation portions may each be divided into a plurality of third-first encapsulation portions and a plurality of third-second encapsulation portions. For example, the plurality of third encapsulation portions may each respectively include the plurality of third-first encapsulation portions and the plurality of third-second encapsulation portions. The plurality of third-first encapsulation portions may overlap the plurality of third-first display areas DA3-1. The plurality of third-first encapsulation portions may overlap the plurality of light-emitting elements LED. The plurality of third-second encapsulation portions may overlap the plurality of third-second display areas DA3-2. The plurality of third-second encapsulation portions may be arranged between the plurality of third-first encapsulation portions. For example, the third-second encapsulation portion may be arranged between two neighboring third-first encapsulation portions. The plurality of third-first encapsulation portions and the plurality of third-second encapsulation portions may be alternately arranged in the second direction (e.g., the +y direction and/or the -y direction).

The first substrate portion (see 410 of FIG. 10) may overlap the first encapsulation portion (see 510 of FIG. 10). For example, the first-first substrate portion (411, FIG. 10) may overlap the first-first encapsulation portion (see 511 of FIG. 10), and the first-second substrate portion (see 412 of FIG. 10) may overlap the first-second encapsulation portion (see 512 of FIG. 10). In addition, the second substrate portion

(see 420 of FIG. 11) may overlap the second encapsulation portion (see 520 of FIG. 11). The third substrate portion may overlap the third encapsulation portion. For example, the third-first substrate portion may overlap the third-first encapsulation portion, and the third-second substrate portion may overlap the third-second encapsulation portion. In addition, the second substrate portion (see 420 of FIG. 11) may overlap the second encapsulation portion (see 520 of FIG. 11).

In one or more embodiments, in the display panel 10, the modulus of each of the first display area DA1 and the third display area DA3 may be greater than the modulus of the second display area DA2.

For example, the modulus of at least one of (e.g., at least one selected from among) the plurality of first substrate portions (see 410 of FIG. 10) may be greater than the modulus of at least one of (e.g., at least one selected from among) the plurality of second substrate portions (see 420 of FIG. 11). The modulus of at least one of (e.g., at least one selected from among) the plurality of third substrate portions may be greater than the modulus of at least one of (e.g., at least one selected from among) the plurality of second substrate portions (see 420 of FIG. 11). For example, the modulus of each of the plurality of first substrate portions (see 410 of FIG. 10) may be greater than the modulus of each of the plurality of second substrate portions (see 420 of FIG. 11). The modulus of each of the plurality of third substrate portions may be greater than the modulus of each of the plurality of second substrate portions (see 420 of FIG. 11).

For example, the modulus of at least one of (e.g., at least one selected from among) the plurality of first-second substrate portions (see 412 of FIG. 10) may be greater than the modulus of at least one of (e.g., at least one selected from among) the plurality of second substrate portions (see 420 of FIG. 11). The modulus of at least one of (e.g., at least one selected from among) the plurality of third-second substrate portions may be greater than the modulus of at least one of (e.g., at least one selected

from among) the plurality of second substrate portions (see 420 of FIG. 11). For example, in one or more embodiments, the modulus of each of the plurality of first-first substrate portions (see 411 of FIG. 10) may be equal to the modulus of each of the plurality of first-second substrate portions (see 412 of FIG. 10). The modulus of each of the plurality of third-first substrate portions may be equal to the modulus of each of the plurality of third-second substrate portions.

For example, the modulus of at least one of (e.g., at least one selected from among) the plurality of first encapsulation portions (see 510 of FIG. 10) may be greater than the modulus of at least one of (e.g., at least one selected from among) the plurality of second encapsulation portions (see 520 of FIG. 11). The modulus of at least one of (e.g., at least one selected from among) the plurality of third encapsulation portions may be greater than the modulus of at least one of (e.g., at least one selected from among) the plurality of second encapsulation portions (see 520 of FIG. 11). For example, in one or more embodiments, the modulus of each of the plurality of first encapsulation portions (see 510 of FIG. 10) may be greater than the modulus of each of the plurality of second encapsulation portions (see 520 of FIG. 11). The modulus of each of the plurality of third encapsulation portions may be greater than the modulus of each of the plurality of second encapsulation portions (see 520 of FIG. 11).

For example, the modulus of at least one of (e.g., at least one selected from among) the plurality of first-second encapsulation portions (see 512 of FIG. 10) may be greater than the modulus of at least one of (e.g., at least one selected from among) the plurality of second encapsulation portions (see 520 of FIG. 11). The modulus of at least one of (e.g., at least one selected from among) the plurality of third-second encapsulation portions may be greater than the modulus of at least one of (e.g., at least one selected from among) the plurality of second encapsulation portions (see 520 of FIG. 11). For example, in one or more embodiments, the modulus of each of the plurality of first-first encapsulation portions (see 511 of FIG. 10) may be equal to the

modulus of each of the plurality of first-second encapsulation portions (see 512 of FIG. 10). The modulus of each of the plurality of third-first encapsulation portions may be equal to the modulus of each of the plurality of third-second encapsulation portions.

In such a structure, in a process in which the display panel 10 is concurrently (e.g., simultaneously) stretched in the first direction (e.g., the +x direction and/or the -x direction) and the second direction (e.g., the +y direction and/or the -y direction), the resolution degradation due to non-uniform positional changes of the plurality of light-emitting elements LED may be reduced.

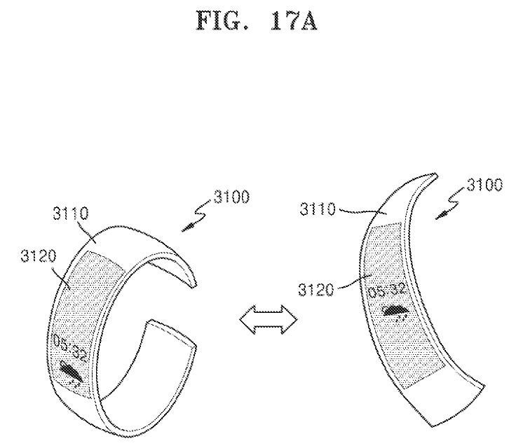

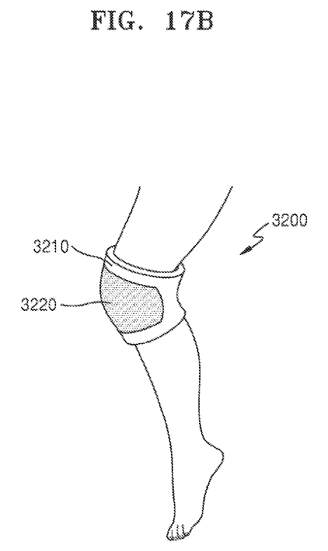

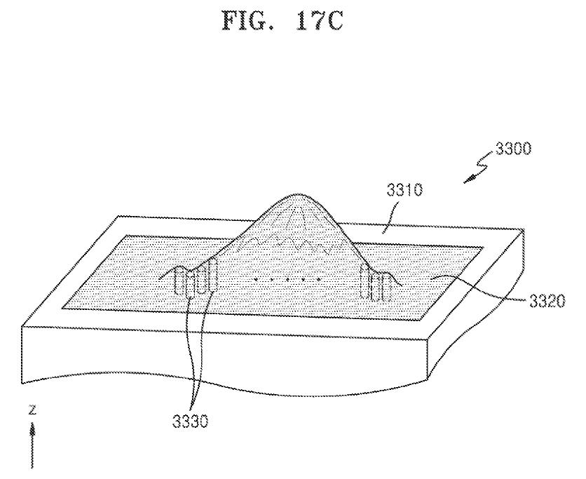

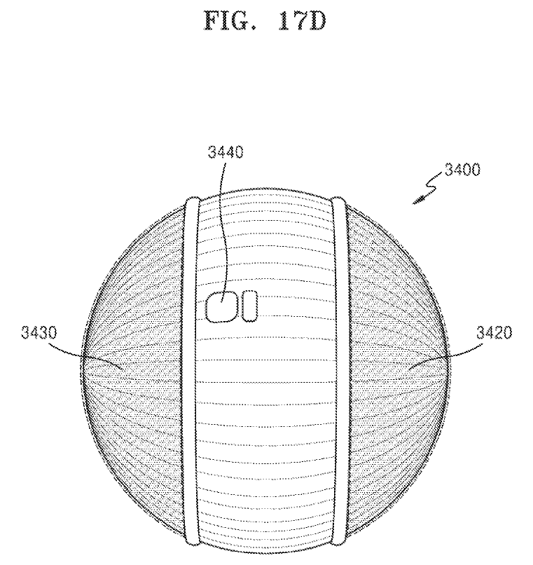

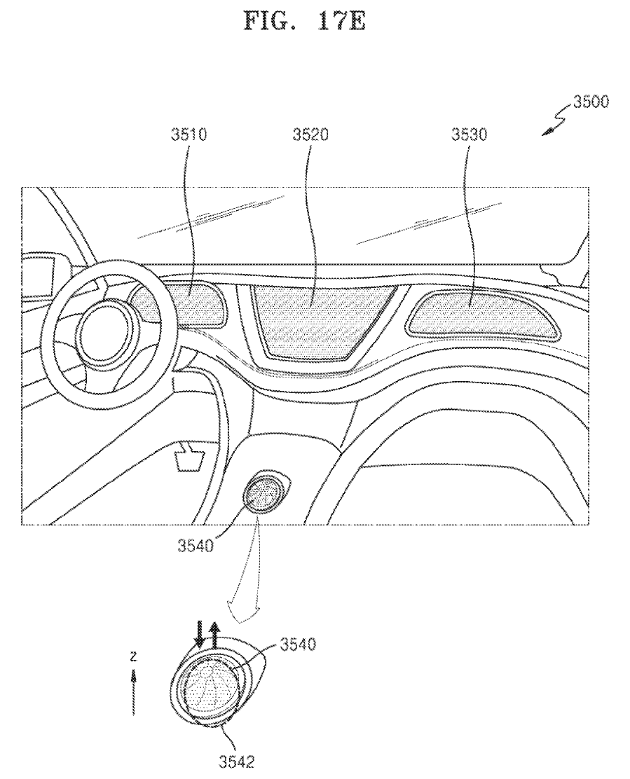

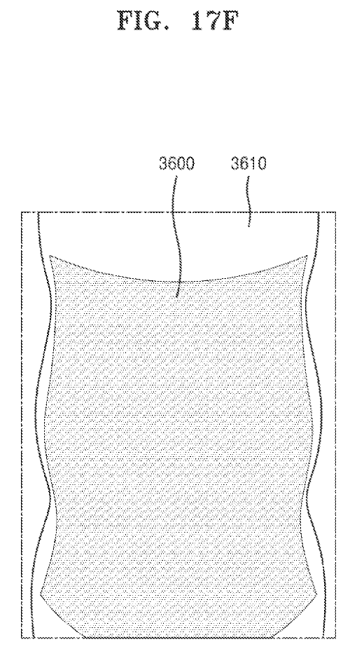

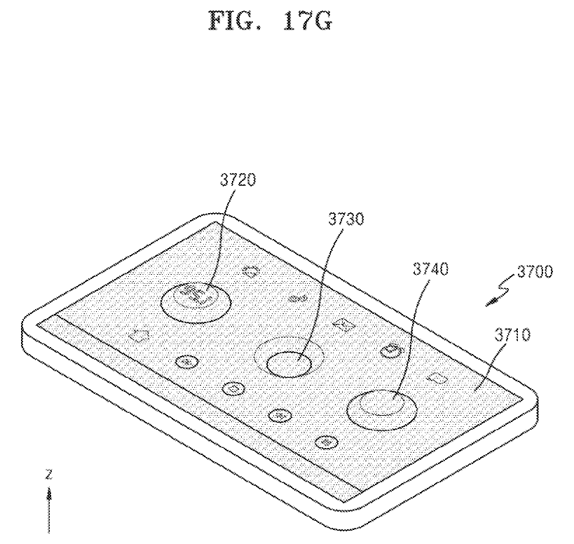

FIGS. 17A to 17G are perspective views schematically illustrating embodiments of electronic devices each including a display panel according to one or more embodiments of the present disclosure.

Referring to FIG. 17A, the display panel according to one or more embodiments may be used in a wearable electronic device 3100 that is wearable on a part of a user's body. The wearable electronic device 3100 may include a body 3110 and a display 3120 provided on the body 3110. The display panel according to one or more embodiments may be used as the display 3120 of the wearable electronic device 3100. As illustrated in FIG. 17A, the wearable electronic device 3100 may be variously modified. In one or more embodiments, the wearable electronic device 3100 may be used as a smart watch or a smartphone according to a user’s choice.

FIG. 17B illustrates a medical electronic device 3200. In one or more embodiments, a medical electronic device 3200 may include a body 3210 and a light emitter 3220. The display panel according to one or more embodiments may be used as the light emitter 3220 of the medical electronic device 3200. The light emitter 3220 may be configured to emit light of a certain wavelength band (e.g., infrared light, visible light, and/or the like) to a patient's body. In one or more embodiments, the body 3210 may include a stretchable fiber material and may have a structure that is wearable on the body of a user who uses the light emitter.

FIG. 17C illustrates an educational electronic device 3300. In one or more embodiments, the educational electronic device 3300 may include a display 3320 provided in a frame 3310. The display 3320 may use the display panel according to one or more embodiments. The display 3320 may be configured to provide images, such as a sea with waves, a mountain covered with snow, or a volcano with flowing lava. In this regard, the display 3320 may extend in a height direction (e.g., the +z direction) to reflect the height of the waves, the mountain, or the volcano. In one or more embodiments, a portion of the display 3320 may show the movement of lava in three dimensions by sequentially changing the height in the direction along which the lava flows. The educational electronic device 3300 may include a plurality of pins (or stroke portions) 3330 arranged on the back surface of the display 3320 so that the display 3320 is stretched in the height direction. As the pins 3330 move in the third direction (e.g., the +z direction or the -z direction), the image displayed on the display 3320 may be implemented to have a three-dimensional height. Although FIG. 17C illustrates the educational electronic device 3300, the use of the educational electronic device 3300 is not limited as long as the educational electronic device 3300 provides certain image information.

The electronic devices illustrated in FIGS. 17A to 17C are described as being variable in shape, but embodiments of the present disclosure are not limited thereto. As in one or more embodiments to be described below, the display panel according to one or more embodiments may be used in an electronic device in which a part (e.g., a screen) capable of displaying an image is fixed.

FIG. 17D illustrates a robot 3400 as an electronic device according to one or more embodiments. The robot 3400 may recognize movement or objects by using a camera 3440 and may display certain images to a user on displays 3420 and 3430. In one or more embodiments, because the display panels according to one or more embodiments may be stretched in one or more suitable directions, as described above,

the display panels may be assembled into a body frame having a hemispherical shape. Accordingly, the robot 3400 may include the hemispherical displays 3420 and 3430.

FIG. 17E illustrates a vehicle display device 3500 as an electronic device according to one or more embodiments. The vehicle display device 3500 may include a cluster 3510, a center information display (CID) 3520, and/or a co-driver display (or a passenger display) 3530. Because the display panel according to one or more embodiments may be stretched in one or more suitable directions, the display panel may be used in the cluster 3510, the CID 3520, and/or the co-driver display (or the passenger display) 3530, regardless of the shape of the internal frame of the vehicle.

Although FIG. 17E illustrates that the cluster 3510, the CID 3520, and/or the co-driver display (or the passenger display) 3530 are separated from one another, embodiments of the present disclosure are not limited thereto. In one or more embodiments, two or more selected from among the cluster 3510, the CID 3520, and the co-driver display (or the passenger display) 3530 may be integrally connected to one another.

In one or more embodiments, the vehicle display device 3500 may include a button 3540 configured to display a certain image. Referring to the enlarged view of FIG. 17E, the hemispherical button 3540 may include an object 3542 configured to provide the feeling of using the button while moving in the +z direction or the -z direction, and a display device arranged on the object 3542. In one or more embodiments, if (e.g., when) the object 3542 has a three-dimensionally round surface, the display device may also have a three-dimensionally round surface.

FIG. 17F illustrates that the electronic device according to one or more embodiments is an advertising or exhibition electronic device 3600. In one or more embodiments, the advertising or exhibition electronic device 3600 may be installed on a fixed structure 3610, such as a wall or a pillar. If (e.g., when) the structure 3610 includes an uneven surface as illustrated in FIG. 17F, the advertising or exhibition

electronic device 3600 may also be arranged along the uneven surface of the structure 3610. In one or more embodiments, the advertising or exhibition electronic device 3600 may be installed on the structure 3610 by using a heat-shrinkable film and/or the like.

FIG. 17G illustrates that the electronic device according to one or more embodiments is a controller 3700. The controller 3700 may include an image-type (kind) button. For example, the controller 3700 may include first to third button areas 3720, 3730, and 3740 in which a portion of a display 3710 protrudes in the +z direction or protrudes in the -z direction (or is recessed in the +z direction). In one or more embodiments, the first and third button areas 3720 and 3740 may protrude in the +z direction, and the second button area 3730 may protrude in the -z direction (or may be recessed in the +z direction).

According to one or more embodiments, a display device, which has improved stretchability and implements excellent or suitable quality of image, and an electronic device including the display device may be provided. The effects described above are illustrative and explanatory, and the effects of the disclosure are not limited to those described above.

In the context of the present application and unless otherwise defined, the terms "use," "using," and "used" may be considered synonymous with the terms "utilize," "utilizing," and "utilized," respectively.

Spatially relative terms, such as “beneath,” “below,” “lower,” “above,” “upper,” and/or the like, may be used herein for descriptive purposes, and, thereby, to describe one element or feature’s relationship to another element(s) or feature(s) as shown in the drawings. Spatially relative terms are intended to encompass different orientations of a device in use, operation, and/or manufacture in addition to the orientation depicted in the drawings. For example, if (e.g., when) the device in the drawings is turned upside down, elements described as “below” or “beneath” other elements or features would then be oriented “above” the other elements or features. Thus, in one or more

embodiments, the example term “below” may encompass both (e.g., simultaneously) an orientation of above and below directions. Furthermore, the device may be otherwise oriented (e.g., rotated 90 degrees or at other orientations), and, as such, the spatially relative descriptors used herein interpreted accordingly.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The display device, the electronic device/apparatus, the display device-manufacturing apparatus, or any other relevant apparatuses/devices or components according to embodiments of the present disclosure described herein may be

implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A display device having a display area and a non-display area, the display device comprising:
a substrate; and
a plurality of light-emitting elements on the substrate and apart from one another along a first direction and a second direction crossing the first direction,
wherein the display area comprises:
a plurality of first display areas extending in the first direction, overlapping the plurality of light-emitting elements arranged along the first direction, and apart from one another along the second direction; and
a plurality of second display areas extending in the first direction, overlapping the plurality of light-emitting elements arranged along the first direction, and each arranged between two first display areas adjacent to each other among the plurality of first display areas,
wherein the substrate comprises:
a plurality of first substrate portions respectively overlapping the plurality of first display areas; and
a plurality of second substrate portions respectively overlapping the plurality of second display areas, and
wherein a modulus of at least one selected from among the plurality of first substrate portions is greater than a modulus of at least one selected from among the plurality of second substrate portions.

2. The display device of claim 1, further comprising an encapsulation portion on the plurality of light-emitting elements,
wherein the encapsulation portion comprises:
a plurality of first encapsulation portions respectively overlapping the plurality of first display areas; and
a plurality of second encapsulation portions respectively overlapping the plurality of second display areas, and
wherein the plurality of first encapsulation portions comprises:
a plurality of first-first encapsulation portions respectively overlapping the plurality of light-emitting elements; and
a plurality of first-second encapsulation portions arranged between the plurality of first-first encapsulation portions.

3. The display device of claim 2, wherein a modulus of at least one selected from among the plurality of first-second encapsulation portions is greater than a modulus of at least one selected from among the plurality of second encapsulation portions.

4. The display device of claim 3, wherein a modulus of at least one selected from among the plurality of first-first encapsulation portions is equal to a modulus of at least one selected from among the plurality of first-second encapsulation portions.

5. The display device of claim 1, wherein the plurality of light-emitting elements comprise:
a plurality of first light-emitting elements arranged in a same column and each electrically connected to a first signal line; and
a plurality of second light-emitting elements arranged in a same column as the plurality of first light-emitting elements and each electrically connected to a second signal line.

6. The display device of claim 1, further comprising an auxiliary light-emitting element arranged between two light-emitting elements adjacent to each other among the plurality of light-emitting elements,
wherein the auxiliary light-emitting element is turned on when the substrate is stretched in the first direction and is turned off when the substrate is compressed in the first direction.

7. The display device of claim 6, wherein the auxiliary light-emitting element is in at least one selected from among the plurality of second display areas.

8. The display device of claim 6, wherein the auxiliary light-emitting element is in plurality, and
the plurality of auxiliary light-emitting elements are apart from one another along the second direction.

9. The display device of claim 6, wherein the plurality of light-emitting elements are arranged at equal intervals from each other along the first direction.

10. The display device of claim 1, wherein the plurality of light-emitting elements are in a grid form.

11. A display device having a display area and a non-display area, the display device comprising:
a substrate;
a plurality of light-emitting elements on the substrate and apart from one another along a first direction and a second direction crossing the first direction; and
an encapsulation portion on the plurality of light-emitting elements,
wherein the display area comprises:
a plurality of first display areas extending in the first direction, overlapping the plurality of light-emitting elements arranged along the first direction, and apart from one another along the second direction; and
a plurality of second display areas extending in the first direction, overlapping the plurality of light-emitting elements arranged along the first direction, and each arranged between two first display areas adjacent to each other among the plurality of first display areas,
wherein the encapsulation portion comprises:
a plurality of first encapsulation portions respectively overlapping the plurality of first display areas; and
a plurality of second encapsulation portions respectively overlapping the plurality of second display areas, and
wherein a modulus of at least one selected from among the plurality of first encapsulation portions is greater than a modulus of at least one selected from among the plurality of second encapsulation portions.

12. The display device of claim 11, wherein the substrate comprises:
a plurality of first substrate portions respectively overlapping the plurality of first display areas; and
a plurality of second substrate portions respectively overlapping the plurality of second display areas, and
wherein the plurality of first substrate portions comprises:
a plurality of first-first substrate portions respectively overlapping the plurality of light-emitting elements; and
a plurality of first-second substrate portions arranged between the plurality of first-first substrate portions.

13. The display device of claim 12, wherein a modulus of at least one selected from among the plurality of first-second substrate portions is greater than a modulus of at least one selected from among the plurality of second substrate portions.

14. The display device of claim 13, wherein a modulus of at least one selected from among the plurality of first-second substrate portions is equal to a modulus of at least one selected from among the plurality of first-first substrate portions.

15. The display device of claim 11, wherein the plurality of light-emitting elements comprise:
a plurality of first light-emitting elements arranged in a same column and each electrically connected to a first signal line; and
a plurality of second light-emitting elements arranged in a same column as the plurality of first light-emitting elements and each electrically connected to a second signal line.

16. The display device of claim 11, further comprising an auxiliary light-emitting element arranged between two light-emitting elements adjacent to each other among the plurality of light-emitting elements,
wherein the auxiliary light-emitting element is turned on when the substrate is stretched in the first direction and is turned off when the substrate is compressed in the first direction.

17. The display device of claim 16, wherein the auxiliary light-emitting element is in at least one selected from among the plurality of second display areas.

18. The display device of claim 16, wherein the auxiliary light-emitting element is in plurality, and
the plurality of auxiliary light-emitting elements are apart from one another along the second direction.

19. The display device of claim 16, wherein the plurality of light-emitting elements are arranged at equal intervals from each other along the first direction.

20. The display device of claim 11, wherein the plurality of light-emitting elements are in a grid form.

21. An electronic device having a display area and a non-display area, the electronic device comprising a stretchable display panel,
wherein the stretchable display panel comprises:
a substrate;
a plurality of light-emitting elements on the substrate and apart from one another along a first direction and a second direction crossing the first direction,
wherein the display area comprises:
a plurality of first display areas extending in the first direction, overlapping the plurality of light-emitting elements arranged along the first direction, and apart from one another along the second direction; and
a plurality of second display areas extending in the first direction, overlapping the plurality of light-emitting elements arranged along the first direction, and each arranged between two first display areas adjacent to each other among the plurality of first display areas,
wherein the substrate comprises:
a plurality of first substrate portions respectively overlapping the plurality of first display areas; and
a plurality of second substrate portions respectively overlapping the plurality of second display areas, and
wherein a modulus of at least one selected from among the plurality of first substrate portions is greater than a modulus of at least one selected from among the plurality of second substrate portions.
